(19) United States
(12) Patent Application Publication
(10) Pub. No.: US 2015/0034929 A1
(43) Pub. Date: Feb. 5, 2015

(54) ORGANIC ELECTROLUMINESCENCE ELEMENT

(71) Applicant: PANASONIC CORPORATION, Osaka (JP)

(72) Inventors: Nobuhiro Ide, Osaka (JP); Kazuyuki Yamae, Nara (JP); Shintaro Hayashi, Hyogo (JP); Yuko Suzuka, Osaka (JP); Yoshikazu Kuzuoka, Osaka (JP); Hitomichi Takano, Osaka (JP); Masuyuki Ota, Osaka (JP)

(21) Appl. No.: 14/380,472

(22) PCT Filed: Feb. 28, 2013
(86) PCT No.: PCT/JP2013/001202

§ 371 Date: Aug. 22, 2014

(30) Foreign Application Priority Data
Mar. 12, 2012 (JP) 2012-054428

(51) Int. Cl. H01L 51/52

(52) U.S. Cl. CPC H01L 51/5246; H01L 51/5275; H01L 51/5268; H01L 51/5253; H01L 51/5212; H01L 51/5228
USPC 257/40

(57) ABSTRACT

The organic electroluminescence element in accordance with the present invention includes: a substrate; a light-outcoupling layer situated on a surface of the substrate; a light-emitting layer situated on a face on an opposite side of the light-outcoupling layer from the substrate; a sealing base situated facing the face of the light-outcoupling layer; and a sealing bond formed to enclose the light-emitting layer and bond the sealing base to the face of the light-outcoupling layer. The light-outcoupling layer includes: a first portion where the light-emitting layer is situated; a second portion where the sealing bond is situated; and a groove spatially separating the first portion from the second portion.

### TECHNICAL FIELD

The present invention relates to organic electroluminescence elements.

### BACKGROUND ART

Recently, organic electroluminescence elements (hereinafter referred to as, “organic EL elements”) have been applied in the applications of illumination panels or the like. Known has been an organic EL element in which a light transmissive first electrode (anode), an organic layer composed of a plurality of layers including a light-emitting layer, and a second electrode (cathode) are stacked on a surface of a light transmissive substrate in this order. In the organic EL element, light produced in the light-emitting layer by applying a voltage between the anode and the cathode is extracted outside through the light transmissive electrode and substrate.

Generally, the light produced in the light-emitting layer may be absorbed by the substrate or lost by total reflection at layer interfaces, and this causes a decrease in an amount of light. Hence, an amount of the light emitted outside is less than a theoretical amount of the light produced in the light-emitting layer. Therefore, improvement of the light-outcoupling efficiency to achieve higher luminance is one of problems to be solved in the field of the organic electroluminescence elements. One of known solutions to improve the light-outcoupling efficiency is to provide a light-outcoupling layer between the first electrode and the surface of the light transmissive substrate. Owing to the light-outcoupling layer, it is possible to suppress total reflection at an interface between the substrate and the electrode and extract a larger amount of light to the outside.

Since the organic layer of the organic EL element is likely to be degraded by moisture, it is important for the organic EL element to prevent moisture intrusion into the element (see document 1 [JP 2005-108824 A]). Degradation of the organic layer causes insufficient light emission efficiency and a drop in reliability of the organic EL element. For protection of the organic layer from moisture, a stack including the organic layer is normally covered with a sealing member bonded to the light transmissive substrate and isolated from the outside.

When the light transmissive substrate and the sealing member are of glass materials, since the glass materials are resistant to moisture penetration, moisture intrusion therethrough is less likely to occur. However, a bonding material to bond the light transmissive substrate to the cover is often a resin. Since the resin is higher permeable to moisture than glass is, moisture intrusion through the resin may cause problems.

FIG. 13 shows an example of the organic EL element. In this organic EL element, a light-outcoupling layer 1002 is provided to a surface of a light transmissive substrate 1001. Provided to a surface of this light-outcoupling layer 1002 is a light-emitting stack 1010 including a first electrode 1003 with light transmissive properties, an organic layer 1004, and a second electrode 1005 which are arranged in this order. Additionally, a sealing base 1006 facing the light transmissive substrate 1001 is bonded to the light transmissive substrate 1001 with a sealing bond 1007 surrounding a periphery of the light-emitting stack 1010.

Further, two types of extension electrodes 1011, that is, a first extension electrode 1011a electrically connected to the first electrode 1003 and a second extension electrode 1011b electrically connected to the second electrode 1005, are formed to extend from an inside to an outside of a sealed region. This extension electrode 1011 is made of a transparent electrically conductive layer for forming the first electrode 1003. The first extension electrode 1011a and the second extension electrode 1011b are provided so as not to be in contact with each other for electric insulation.

According to this configuration, light produced in the light-emitting stack 1010 enters the transparent substrate 1001 through the light-outcoupling layer 1002 and then emerges outside. Hence, a larger amount of light can emerge.

Note that, regarding FIG. 13(a), to clearly illustrate the structure of the element, the sealing base 1006 is not shown, and a region to which the sealing bond 7 is to be provided is indicated with dot pattern. Additionally, a periphery of the electrically conductive layer constituting the first electrode 1003 and a periphery of the organic layer 1004 are not visible from outside but are indicated by broken lines. FIG. 13(b) shows a combination of sections taken along lines X-Y-Z of FIG. 13(a), and an end close to the first extension electrode 1011a is shown on a left side, and an end close to the second extension electrode 1011b is shown on a right side.

In the organic EL element with a structure shown in FIG. 13, the light-outcoupling layer 1002 is formed on the surface of the light transmissive substrate 1001. For this reason, when moisture intrudes into the light-outcoupling layer 1002 from the outside of the element, such moisture may further intrude into the inside of the element through the light-outcoupling layer 1002 and finally arrive at the organic layer 1004. This may cause deterioration of the organic layer 1004. Additionally, inside the sealed region, a part of the surface of the light-outcoupling layer 1002 is exposed between the first extension electrode 1011a and the second extension electrode 1011b, and thus moisture may intrude inside the element through such a part.

To inhibit intrusion of moisture through the light-outcoupling layer 1002, one solution may be to make the light-outcoupling layer 1002 of moisture proof material. However, when the light-outcoupling layer 1002 is made of moisture proof material, a layer of moisture proof material is required to satisfy the desired light transmissive properties and the desired light-outcoupling efficiency and yet satisfy the desired moisture proof properties. Hence, it may be difficult to easily form the light-outcoupling layer 1002.

### SUMMARY OF INVENTION

In view of the above insufficiency, the present invention has aimed to propose an organic electroluminescence element which has a superior light-outcoupling efficiency and yet can inhibit moisture intrusion efficiently and thus is highly reliable and is less likely to deteriorate.

The organic electroluminescence element of the first aspect in accordance with the present invention includes: a substrate; a light-outcoupling layer situated on a surface of the substrate; a light-emitting layer situated on a face on an opposite side of the light-outcoupling layer from the substrate; a sealing base situated facing the face of the light-outcoupling layer; and a sealing bond formed to enclose the light-emitting layer and bond the sealing base to the face of the light-outcoupling layer. The light-outcoupling layer includes; a first portion where the light-emitting layer is situated; a second portion where the sealing bond is situated; and a groove spatially separating the first portion from the second portion.

According to the organic electroluminescence element of the second aspect in accordance with the present invention depending on the first aspect, the organic electroluminescence element comprises an extension electrode electrically connected to the light-emitting layer. The extension electrode is situated between the face of the light-outcoupling layer and the sealing bond so as to extend across the sealing bond.

According to the organic electroluminescence element of the third aspect in accordance with the present invention depending on the second aspect, the extension electrode is formed to cover the second portion.

According to the organic electroluminescence element of the fourth aspect in accordance with the present invention depending on the second or third aspect, the organic electroluminescence element comprises an electrode connector electrically connecting the light-emitting layer to the extension electrode. The electrode connector is formed to extend across the groove along an internal surface of the groove.

According to the organic electroluminescence element of the fifth aspect in accordance with the present invention depending on the fourth aspect, the light-emitting layer includes: a first electrode situated on the face of the light-outcoupling layer; a second electrode situated facing a face on an opposite side of the first electrode from the light-outcoupling layer; and an organic layer interposed between the first electrode and the second electrode and configured to emit light in response to application of a voltage between the first electrode and the second electrode. The extension electrode includes a first extension electrode and a second extension electrode. The electrode connector includes a first electrode connector electrically connecting the first electrode to the first extension electrode and a second electrode connector electrically connecting the second electrode to the second extension electrode. The second electrode connector is formed integrally with the second electrode.

According to the organic electroluminescence element of the sixth aspect in accordance with the present invention depending on the fifth aspect, the first electrode connector is formed of a part separated from an electrically conductive layer to be a base of the second electrode.

According to the organic electroluminescence element of the seventh aspect in accordance with the present invention depending on any one of the first to sixth aspects, at least one of both side faces of the groove is an inclined surface that is inclined from the surface of the substrate.

According to the organic electroluminescence element of the eighth aspect in accordance with the present invention depending on any one of the first to seventh aspects, the organic electroluminescence element comprises a protector protecting the light-emitting layer. The protector is formed by filling with filler a space enclosed by the substrate, the sealing base, and the sealing bond.

According to the organic electroluminescence element of the ninth aspect in accordance with the present invention depending on the eighth aspect, the filler contains a hygroscopic agent.

According to the organic electroluminescence element of the tenth aspect in accordance with the present invention depending on any one of the second to ninth aspects, a total of a thickness of the extension electrode and a thickness of a portion of the sealing bond positioned on this extension electrode is greater than a thickness of the light-emitting layer.

According to the organic electroluminescence element of the eleventh aspect in accordance with the present invention depending on any one of the first to tenth aspects, the substrate is made to transmit light emitted from the light-emitting layer.

According to the organic electroluminescence element of the twelfth aspect in accordance with the present invention depending on the eleventh aspect, the light-outcoupling layer includes at least one of a light refraction layer and a light scattering layer. The light refraction layer is a layer having a refractive index between a refractive index of a portion of the light-emitting layer that is in contact with the light-outcoupling layer and a refractive index of the substrate. The light scattering layer is a layer having a structure causing scattering of light emitted from the light-emitting layer.

According to the organic electroluminescence element of the thirteenth aspect in accordance with the present invention depending on any one of the first to twelfth aspects, the substrate and the sealing base are made of moisture proof material.

### BRIEF DESCRIPTION OF THE DRAWINGS

FIG. 1(a) is a plan illustrating the organic electroluminescence element of the first embodiment, and FIG. 1(b) is a combination of cross sectional views taken along lines X-Y-Z of FIG. 1(a).

FIG. 2 is a combination of sections illustrating the organic electroluminescence element of the second embodiment.

FIG. 3(a) is a plan illustrating the organic electroluminescence element of the third embodiment, and FIG. 3(b) is a combination of sections taken along lines X-Y-Z of FIG. 3(a).

FIG. 4(a) is a plan illustrating the organic electroluminescence element of the fourth embodiment, and FIG. 4(b) is a combination of sections taken along lines X-Y-Z of FIG. 4(a).

FIG. 5 is a combination of sections illustrating the organic electroluminescence element of the fifth embodiment.

FIG. 6 is a combination of sections illustrating the modification of the organic electroluminescence element of the fifth embodiment.

FIG. 7 is an explanatory view illustrating the method of manufacturing the organic electroluminescence element of the first embodiment.

FIG. 8 is an explanatory view illustrating the method of manufacturing the organic electroluminescence element of the first embodiment.

FIG. 9 is an explanatory view illustrating the method of manufacturing the organic electroluminescence element of the first embodiment.

FIG. 10 is an explanatory view illustrating the method of manufacturing the organic electroluminescence element of the first embodiment.

FIG. 11 is an explanatory view illustrating the method of manufacturing the organic electroluminescence element of the first embodiment.

FIG. 12 is an explanatory view illustrating the method of manufacturing the organic electroluminescence element of the first embodiment.

FIG. 13(a) is a plan illustrating the organic electroluminescence element of the background art, and FIG. 13(b) is a combination of sections taken along lines X-Y-Z of FIG. 13(a).

### DESCRIPTION OF EMBODIMENTS

### First Embodiment

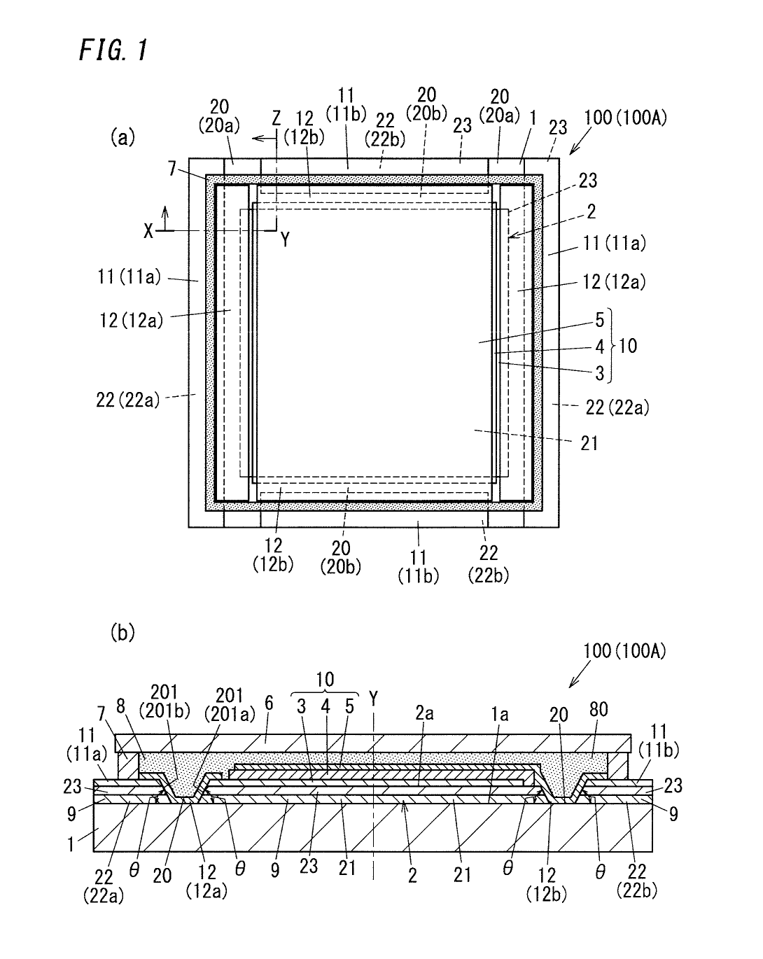

FIGS. 1(a) and (b) show the organic electroluminescence element (organic EL element) 100 (100A) of the first embodiment.

As shown in FIG. 1(b), this organic EL element 100A includes a substrate (light transmissive substrate) 1 having a surface (in FIG. 1(b), an upper surface of the light transmissive substrate 1) 1a to which a light-outcoupling layer 2 is provided. In the organic EL element 100A, a light-emitting stack (light-emitting layer) 10 is provided to a surface (in FIG. 1(b), an upper surface of the light-outcoupling layer 2) 2a of the light-outcoupling layer 2 of the substrate 1, and includes a first electrode 3 having light transmissive properties, an organic layer 4, and a second electrode 5 that are stacked in this order.

A sealing base 6 facing the light transmissive substrate 1 is bonded to the light transmissive substrate (substrate) 1 with a sealing bond 7 to surround a periphery of the light-emitting stack 10, and thus the light-emitting stack 10 is enclosed.

In the organic EL element 100A, in a planar view (in a case where the organic EL element 100A is seen in a direction perpendicular to the surface of the light transmissive substrate 1), a region enclosed by the sealing bond 7 defines a sealed region.

In brief, the organic EL element 100A of the present embodiment includes: the substrate 1; the light-outcoupling layer 2 situated on the surface 1a of the substrate 1; the light-emitting layer (light-emitting stack) 10 situated on the face 2a on an opposite side of the light-outcoupling layer 2 from the substrate 1; the sealing base 6 situated facing the face 1a of the light-outcoupling layer 2; and the sealing bond 7 formed to enclose the light-emitting layer 10 and bond the sealing base 6 to the face 1a of the light-outcoupling layer 2.

Note that, regarding FIG. 1(a), to clearly illustrating the structure of the organic EL element 100A, the sealing base 6 and the filler 8 are not shown, and a region to which the sealing bond 7 is to be provided is indicated with dot pattern. Additionally, a periphery of the light-outcoupling layer 2 and a periphery of the organic layer 4 are not visible from outside but are indicated by broken lines.

In the present embodiment, an electrically conductive layer for forming the first electrode 3 is provided to a whole of the surface (face) 2a of the light-outcoupling layer 2. For this reason, the broken line representing the periphery of the light-outcoupling layer 2 may also represent a periphery, which is not visible from outside, of the electrically conductive layer for forming the first electrode 3.

FIG. 1(b) shows a combination of sections taken along lines X-Y-Z of FIG. 1(a), and an end close to a first extension electrode 11a is shown on a left side, and an end close to a second extension electrode 11b is shown on a right side.

In the organic EL element 100A of the present embodiment, an extension electrode 11 which extends from an inside of the sealed region to an outside of the sealed region is provided to the surface 2a of the light-outcoupling layer 2.

The extension electrode 11 is constituted by the first extension electrode 11a electrically connected to the first electrode 3 and the second extension electrode 11b electrically connected to the second electrode 5. The first extension electrode 11a and the second extension electrode 11b are formed so as to be electrically insulated from each other. Hence, a voltage can be applied between the first electrode 3 and the second electrode 5 without causing a trouble such as short-circuiting.

In brief, the organic EL element 100A includes the extension electrode 11 electrically connected to the light-emitting layer 10. The extension electrode 11 is situated between the face 2a of the light-outcoupling layer 2 and the sealing bond 7 so as to extend across the sealing bond 7. In the present embodiment, the extension electrode 11 includes the first extension electrode 11a and the second extension electrode 11b.

The light transmissive substrate 1 is a transparent substrate with light transmissive properties, and can be made of a glass substrate. In short, the substrate 1 is made to transmit light emitted from the light-emitting layer 10. Further, the substrate 1 is made of moisture proof material. When the light transmissive substrate 1 is made of a glass substrate, glass has low moisture permeability, and thus it is possible to inhibit intrusion of moisture into the inside of the sealed region. In the present embodiment, the light transmissive substrate 1 is formed into a rectangular shape. Hence, the surface 1a of the substrate 1 is defined by two sides which face each other in a first direction (left and right direction in FIG. 1(a)) and further two sides which face each other in a second direction (upward and downward direction in FIG. 1(a)) perpendicular to the first direction.

In the organic EL element 100A of the present embodiment, the light-outcoupling layer 2 is provided to the surface 1a of the light transmissive substrate 1, and the light-emitting stack 10 is provided to the surface 2a of the light-outcoupling layer 2. In a planar view (in a case where the organic EL element is seen in a direction perpendicular to the surface of the substrate), a region to which the light-emitting stack 10 is provided is a central region of the light transmissive substrate 1. The sealing bond 7 is provided to a surrounding region of the light-emitting stack 10 to extend along the periphery of the light-emitting stack 10, and the light-emitting stack 10 is situated inside the sealed region.

The light-outcoupling layer 2 is a layer which has light transmissive properties and serves to increase an amount of light that is produced by the organic layer 4 and emerges outside through the first electrode 3.

Note that, to improve the light-outcoupling efficiency, it is preferable that a refractive index of the light-outcoupling layer 2 be higher than a refractive index of the light transmissive substrate 1. Light produced by the light-emitting layer (light-emitting stack) reaches the substrate directly or by reflection, and however when a difference between refractive indices at this interface (interface between the light-emitting layer and the substrate) is increased, total reflection is likely to occur and thus an amount of light emerging outside tends to decrease. In contrast, when the light-outcoupling layer 2 having a refractive index close to a refractive index of the first electrode 3 is provided as a layer (layer for light extraction) under the first electrode 3, it is possible to decrease a difference between the refractive indices of the first electrode 3 and the light-outcoupling layer 2. Hence, light-outcoupling efficiency for light entering the light-outcoupling layer 2 can be improved. It is preferable that the difference between the refractive indices of the first electrode 3 and the light-outcoupling layer 2 be smaller. For example, the difference between the refractive indices of the first electrode 3 and the light-outcoupling layer 2 may be 2 or less, or 1 or less, but is not limited to these instances.

In the present embodiment, it is preferable that the light-outcoupling layer 2 include a light-outcoupling structure 9 for increasing an amount of light emerging outside and the light-outcoupling structure 9 be provided to an interface between the light-outcoupling layer 2 and the light transmissive substrate 1. The light-outcoupling structure 9 may be a layer (light scattering layer) which functions to scatter light.

Alternatively, the light-outcoupling structure 9 may be a lens array layer. The lens array layer is a layer having fine protrusions densely arranged in a plane. The protrusions of the lens array layer may be in the shape of hemisphere, pleat, pyramid (quadrangular pyramid) or the like. When the light-outcoupling layer 2 has a light-outcoupling structure 9, light traveling toward the transparent substrate 1 is scattered by the light-outcoupling structure 9 and thus total reflection would be inhibited. Consequently, an amount of light emerging outside can be more increased.

In addition, a light-outcoupling structure unit as a structure for improvement of light-outcoupling efficiency, may be formed on the surface (upper surface of the light transmissive substrate 1) 1a, facing the light-outcoupling layer 2, of the light transmissive substrate 1. It is possible in this way to increase the light-outcoupling efficiency further.

The light-outcoupling structure unit can be prepared by forming an uneven structure on the surface 1a of the light transmissive substrate 1 or by forming a light scattering layer containing a light scattering substance. Alternatively, a light-outcoupling function unit such as a light scattering layer may be also formed additionally on the surface of the light transmissive substrate 1 directed to the outside. The light-outcoupling structure unit or the light-outcoupling function unit is not limited if it is a structure with light transmissive properties.

The light-outcoupling layer 2 may be, for example, a plastic layer. The plastic layer can be formed as a layer of a molded article (such as sheet or film), which is obtained by molding and hardening a synthetic resin as a raw material for plastic, and is to be bonded to the transparent substrate 1. The plastic layer for use may be a layer of a plastic material such as PET (polyethylene terephthalate) or PEN (polyethylene naphthalate). The plastic layer preparing method is not particularly limited. The material for the light-outcoupling layer 2 is preferably flexible. When it is flexible, it is possible to form the light-outcoupling layer 2 on the transparent substrate 1, for example, by supplying the material sequentially from a roll of the material. When the light-outcoupling layer 2 is flexible, it is also possible to prepare a flexible element.

When the light-outcoupling layer 2 is made of a plastic sheet, for example, the light-outcoupling layer 2 can be prepared by bonding the material for the light-outcoupling layer 2 onto the surface 1a of the light transmissive substrate 1. The adhesion may be performed for example by thermal compression or by using an adhesive.

Alternatively, the light-outcoupling layer 2 may be a resin layer. In this case, the light-outcoupling layer 2 can be formed by coating the surface 1a of the light transmissive substrate 1 with a resin material.

Alternatively, the light-outcoupling layer 2 (light scattering layer 9) having a function of scattering light can be formed, for example, by introducing a light scattering substance, such as particles and pores, into a plastic layer.

Alternatively, the light-outcoupling structure 9 can be obtained by roughening a surface of a plastic layer or forming a layer of a light scattering material on the surface of the plastic layer. Scattering of light will be caused by reflection by an uneven interface or a surface of a particle or by reflection or refraction resulting from a difference in refractive index at an interface between different components.

In the present embodiment, the light-outcoupling layer 2 includes a light refraction layer 23 and the light scattering layer 9. The light scattering layer 9 is formed on the surface 1a of the substrate 1. The light refraction layer 23 is formed on a surface (upper surface in FIG. 1(b)) on an opposite side of the light scattering layer 9 from the substrate 1. The light refraction layer 23 is a layer having a refractive index between a refractive index of a portion (the first electrode 3 in the present embodiment) of the light-emitting layer 10 that is in contact with the light-outcoupling layer 2 and a refractive index of the substrate 1. The light scattering layer 9 is a layer having a structure causing scattering of light emitted from the light-emitting layer 10.

The light-emitting stack 10 is a stack of the first electrode 3, the organic layer 4 and the second electrode 5. The light-emitting stack 10 is formed on the surface 2a of the light-outcoupling layer 2. Thus, the light-outcoupling layer 2 can serve as a substrate for formation of the first electrode 3, the organic layer 4 and the second electrode 5. In the present embodiment, a composite substrate of the light transmissive substrate 1 and the light-outcoupling layer 2 can be used as a substrate.

The first electrode 3 and the second electrode 5 are paired electrodes. Normally, the first electrode 3 is an anode and the second electrode 5 is a cathode, but the first electrode 3 may be a cathode and the second electrode 5 may be an anode.

The first electrode 3 is light transmissive, and thus serves as an electrode for light-outcoupling (light transmissive electrode). The second electrode 5 may be light reflective. In such a case, light emitted from the light-emitting layer toward the second electrode 5 may be reflected by the second electrode 5 and thus emerges outside through the light transmissive substrate 1.

Alternatively, the second electrode 5 may be a light transmissive electrode. When the second electrode 5 is light transmissive, a structure allowing light to emit outside through a rear surface (surface close to the sealing base 6) is available. Alternatively, when the second electrode 5 is light transmissive, a light reflective layer may be formed on a rear surface of the second electrode 5 (i.e., an opposite surface from the organic layer 4). In this case, light traveling in a direction close to the second electrode 5 is reflected by the light reflective layer and thus emerges outside through the light transmissive substrate 1. In this regard, the light reflective layer may cause diffuse reflection or specular reflection. The second electrode 5 can be made, for example, of Al or Ag.

The light transmissive electrode may be made of an electrically conductive oxide (e.g., ITO, IZO, AZO, GZO, and SnO₂), an electrically conductive material (e.g., a metal nanowire, a metal thin film, a carbon compound, and an electrically conductive polymer), or a combination of these. For example, the light transmissive electrode may be a metal thin film with a thickness allowing light to pass.

Alternatively, the light transmissive electrode may be constituted by an electrode made of the electrically conductive oxide, the electrically conductive material, or the combination of these, and metal wires with an electric conductivity higher than this electrode and formed on a surface of this electrode. In this case, it is possible to reduce a resistance (sheet resistance) of the light transmissive electrode. Note that, the metal wires are arranged in a stripe or grid pattern so as not to block out all of rays of light from the organic layer 4. Alternatively, instead of the metal wires, a metal thin film with a thickness allowing light to pass may be used.

The organic layer 4, which is a layer functioning to emit light, includes two or more layers appropriately selected from a hole-injecting layer, a hole-transporting layer, a light-emitting layer, an electron-transporting layer, an electron-injecting layer, an intermediate layer, and the like.

The sealing base 6 can be formed by using a low water permeability material. In other words, the sealing base 6 is made of moisture proof material. For example, the sealing base 6 may be made of a glass or metal substrate. The sealing base 6 may or may not include a recess for receiving the light-emitting stack 10. When the sealing base 6 is devoid of such a recess, sealing is conducted while a flat surface the sealing base 6 faces the light transmissive substrate 1. Hence, a substrate with a plate shape can be used as the sealing base 6 without any modification.

The sealing base 6 is bonded to the light transmissive substrate 1 via the sealing bond 7. The sealing bond 7 is formed on the surface 1a of the light transmissive substrate 1 to surround the periphery of the light-emitting stack 10. In the first embodiment shown in FIG. 1, the sealing bond 7 is provided in contact with the extension electrode 11 formed on the surface 2a of the light-outcoupling layer 2 and part of the light transmissive substrate 1 which is exposed via a gap formed by separating each of the extension electrode 11 and the light-outcoupling layer 2. The sealing bond 7 surrounds the periphery of the light-emitting stack 10 and bonds the sealing base 6 to the light transmissive substrate 1, and thus the light-emitting stack 10 is enclosed so as to be isolated from an external space.

The sealing bond 7 is made of a suitable adhesive material. For example, the sealing bond 7 may be a resinous adhesive material. The resinous adhesive material preferably has moisture proof properties. For example, when the resinous adhesive contains a drying agent, it is possible to improve the moisture proof properties. The resinous adhesive material may contain as a main component thermosetting resin or an ultraviolet curable resin.

In the present embodiment, it is preferable that a gap between the light transmissive substrate 1 and the sealing base 6 and housing the light-emitting stack 10 (i.e., a space enclosed by the substrate 1, the sealing base 6, and the sealing bond 7) be filled with filler 8.

In case where the space of the sealed region between the light transmissive substrate 1 and the sealing base 6 is filled with the filler 8, even if the sealing base 6 is bent inward in a process of sealing with the sealing base 6, it is possible to avoid contact of the sealing base 6 with the light-emitting stack 10. Consequently, the element can be manufactured more safely.

The filler 8 may be a curable resin composition containing a drying or hygroscopic agent. When the filler 8 is made of a resin composition that is fluid before cured, it can be easy to fill the gap of the sealed region with the filler 8. In a case where the filler contains a drying or hygroscopic agent, even if moisture intrudes into the inside the element, the filler 8 can absorb such moisture. Thus, it is possible to inhibit moisture from arriving at the organic layer 4.

In other words, the organic EL element 100A may include a protector 80 protecting the light-emitting layer 10. The protector 80 is formed by filling with filler 8 the space enclosed by the substrate 1, the sealing base 6, and the sealing bond 7. In the present embodiment, the filler 8 contains a hygroscopic agent.

Note that, instead of filling the gap of the region (sealed region) formed by the sealing base 6 with the filler 8, a space which is sealed (sealed space) may be formed. In this case, it is preferable that a drying agent be provided inside the sealed space. Thus, even when moisture intrudes into the sealed space, such moisture can be absorbed in the drying agent.

For example, the drying agent may be provided inside the sealed space by attaching the drying agent on a surface of the sealing base 6 facing the light-emitting stack 10. However, in a case where the sealed space is formed and the drying agent is attached, the element is likely to be thick. Hence, to thin the element, it is preferable that the gap is filled with filler 8.

In the organic EL element 100 of the present embodiment, the light-outcoupling layer 2 is separated into a central portion 21 on which the light-emitting stack 10 is formed, and a peripheral portion 22 on which the sealing bond 7 is formed. In other words, inside the sealed region, the light-outcoupling layer 2 is divided in an island manner into the central portion 21 to which the light-emitting stack 10 is provided, and the peripheral portion 22 (also see FIG. 8 described below).

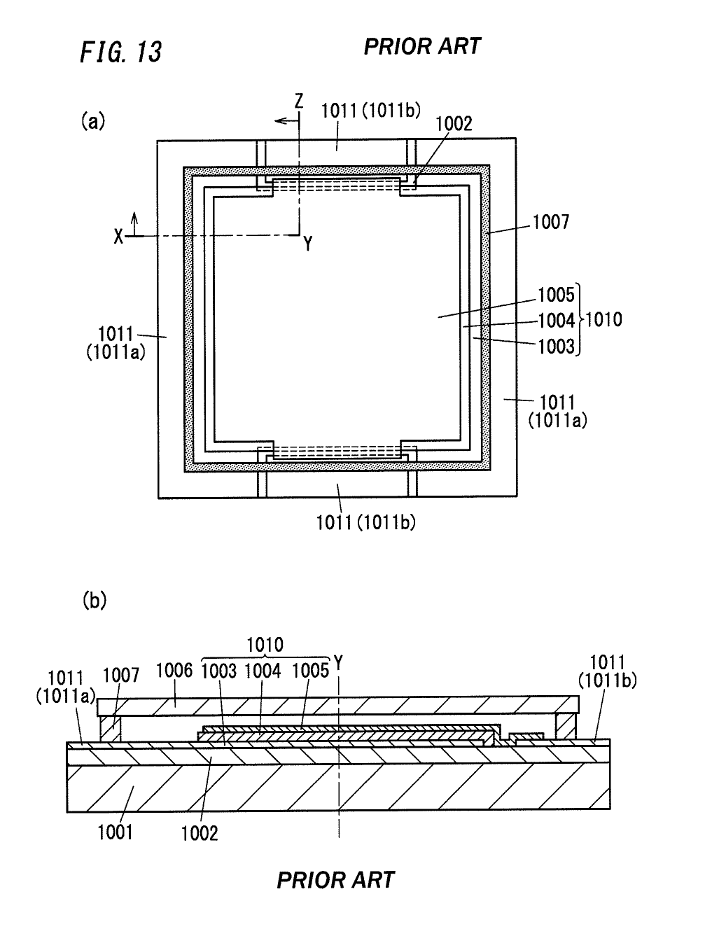

The light-emitting stack 10 is interposed between the light transmissive substrate 1 and the sealing base 6 facing each other, and the periphery of the light-emitting stack 10 is surrounded, and thus is isolated from the outside. Note that, as described with the example shown in FIG. 13, with regard to a structure in which the light-emitting stack 10 formed on the surface 2a of the light-outcoupling layer 2 is enclosed, moisture may intrude into the inside of the element through the light-outcoupling layer 2.

Especially, when the light-outcoupling layer 2 is made of a plastic layer, the light-outcoupling efficiency can be improved but plastic is high moisture permeable and thus a problem of moisture intrusion becomes more serious.

In view of this, in the organic EL element 100A of the present embodiment, the light-outcoupling layer 2 is cut to be separated into the central portion (first portion) 21 and the peripheral portion (second portion) 22.

Hence, the peripheral portion 22 of the light-outcoupling layer 2 is not connected to the central portion 21. Thus, even if moisture intrudes into the peripheral portion 22 of the light-outcoupling layer 2, such moisture cannot reach the central portion 21 by way of the light-outcoupling layer 2.

As described above, intrusion of moisture into the central portion 21 of the light-outcoupling layer 2 is inhibited, and thus it is possible to reduce a possibility that moisture arrives at the organic layer 4 through the central portion 21 of the light-outcoupling layer 2. In summary, the light-outcoupling layer 2 is separated, and therefore intrusion of moisture from the outside can be more inhibited, and deterioration of the element can be reduced.

Between the central portion 21 and the peripheral portion 22 of the light-outcoupling layer 2, a recess (groove) 20 is formed as a result of separation of the light-outcoupling layer 2. The recess 20 of the light-outcoupling layer 2 penetrates the light-outcoupling layer 2, and a bottom of the recess 20 is part of the surface 1a of the light transmissive substrate 1. As described above, when the recess 20 is formed, the light-outcoupling layer 2 can be obtained such that the peripheral portion 22 and the central portion 21 are not physically connected to each other. The recess 20 is formed so as to surround the periphery of the light-emitting stack 10.

In the present embodiment, the light-outcoupling layer 2 includes: the first portion (central portion) 21 on which the light-emitting layer 10 is situated: the second portion (peripheral portion) 22 on which the sealing bond 7 is situated: and the groove (recess) spatially separating the first portion (central portion) 21 from the second portion (peripheral portion) 22.

The first portion 21 is formed in a rectangular shape, and is positioned on a center of the surface 1a of the substrate 1. In the present embodiment, the central portion of the light-outcoupling layer 2 defines the first portion 21. However, the first portion 21 need not necessarily be the central portion of the light-outcoupling layer 2.

The second portion 22 is formed in a rectangular frame shape enclosing the first portion 21. In the present embodiment, the peripheral portion 22 includes two straight second portions (first sides) 22a and two straight second portions (second sides) 22b. The two first sides 22a are formed at opposite ends in a first direction (left and right direction in FIG. 1(a)) of the surface 1a of the substrate 1 and extend along a second direction (upward and downward direction in FIG. 1(a)). The two second sides 22b are formed at opposite ends in the second direction (upward and downward direction in FIG. 1(a)) of the surface 1a of the substrate 1 and extend along the first direction (left and right direction in FIG. 1(a)). In the present embodiment, the peripheral portion of the light-outcoupling layer 2 defines the second portion 22. However, the second portion 22 need not necessarily be the peripheral portion of the light-outcoupling layer 2.

The first sides 22a are spatially separated from the first portion 21 and the second sides 22b by the grooves (first grooves) 20a that are straight and extend along the second direction. Further, the second sides 22b are spatially separated from the first portion 21 by the grooves (second grooves) 20b that are straight and extend along the first direction.

Accordingly, the groove 20 is defined by: side surfaces (end surfaces) 201 (201a) of the central portion (first portion) of the light-outcoupling layer 2: side surfaces (end surfaces) 201 (201b) of the peripheral portion (second portion) individually facing these side surfaces 201a; and the surface 1a of the light transmissive substrate 1.

The whole of the central portion 21 of the light-outcoupling layer 2 is situated inside the sealed region. Further, the peripheral portion 22 of the light-outcoupling layer 2 formed across the periphery (sealing bond 7) of the sealed region so as to extend from the inside to the outside of the sealed region. When the peripheral portion 22 of the light-outcoupling layer 2 extends across the periphery of the sealed region, it is possible to extend the extension electrode 11 to the outside of the sealed region. The sealing bond 7 is formed on the surface of the peripheral portion 22 of the light-outcoupling layer 2, and thus a structure for more inhibiting the intrusion of moisture can be obtained.

In the organic EL element 100A, when a voltage is applied between the first electrode 3 and the second electrode 5, holes and electrons recombine in the organic layer 4 and thus light is produced. Hence, it is necessary to provide electrode terminals which are respectively electrically connected to the first electrode 3 and the second electrode 5 and extend to the outside of the sealed region. The electrode terminals are terminals to be electrically connected to external electrodes. In the first embodiment shown in FIG. 1, the extension electrode 11 formed on the surface 2a of the light-outcoupling layer 2 defines the electrode terminals.

Each first extension electrode 11a electrically connected to the first electrode 3 and each second extension electrode 11b electrically connected to the second electrode 5 are formed on parts of the surface 2a of the light-outcoupling layer 2 over a periphery of the light transmissive substrate 1. In the present embodiment, the extension electrode 11 (the first extension electrodes 11a and the second extension electrodes 11b) is constituted by separate parts formed by cutting an electrically conductive layer for forming the first electrode 3 together with the light-outcoupling layer 2. In brief, the electrically conductive layer constituting the first electrode 3 is provided on the entire surface of the light-outcoupling layer 2, and this electrically conductive layer is separated into a portion on the central part of the substrate forming the first electrode 3 and other portions on the peripheral part of the substrate forming the extension electrode 11.

As described above, the first electrode 3, each first extension electrode 11a, and each second extension electrode 11b are made of the same electrically conductive material. Hence, the organic EL element 100A can be easily manufactured. The electrically conductive layer for the first electrode 3 may be made of transparent metal oxide, for example. Concretely, this electrically conductive layer may be made of ITO.

In the present embodiment, the peripheral portion 22 of the light-outcoupling layer 2 includes: at least one first peripheral portion 22a on which the first extension electrode 11a is provided; and at least one second peripheral portion 22b on which the second extension electrode 11b is provided. The first peripheral portion 22a and the second peripheral portion 22b of the peripheral portion 22 are separated from each other, and thus it is possible to separate portions of the extension electrodes 11 respectively corresponding to the anode and the cathode from each other so as not to cause short-circuiting, even when the extension electrode 11 is formed of the electrically conductive layer provided to the entire surface of the light-outcoupling layer 2.

The recess 20 formed between the central portion 21 and the peripheral portion 22 extends between the first peripheral portion 22a and the second peripheral portion 22b of the light-outcoupling layer 2. The recess 20 between the first peripheral portion 22a and the second peripheral portion 22b can prevent electrical connection between the first extension electrode 11a and the second extension electrode 11b.

In the present embodiment, the extension electrode 11 is provided so as to cover the entire surface of the peripheral portion 22 of the light-outcoupling layer 2, and thus the surface of the peripheral portion 22 of the light-outcoupling layer 2 is covered with the extension electrode 11. In short, the extension electrode 11 is formed to cover the peripheral portion (second portion) 22. Especially, the extension electrode 11 covers the entire surface of the peripheral portion 22 so that the surface (upper surface in FIG. 1(b)) of the peripheral portion 22 is not exposed to the space (sealed space) enclosed by the light transmissive substrate 1, the sealing base 6, and the sealing bond 7. In other words, with regard to the light-outcoupling layer 2, the surface of the first peripheral portion 22a is covered with the first extension electrode 11a and the surface of the second peripheral portion 22b is covered with the second extension electrode 11b.

It is preferable that at least in the sealed region, the surface of the light-outcoupling layer 2 be covered with the extension electrode 11. If in the sealed region, the surface of the light-outcoupling layer 2 is not covered with the extension electrode 11, there is a possibility that moisture intrudes into the inside of the sealed region through an uncovered part of the light-outcoupling layer 2. In contrast, when the surface of the light-outcoupling layer 2 is covered, the intrusion of moisture can be more inhibited.

Additionally, when also in the outside of the sealed region the extension electrode 11 is provided to the entire surface of the peripheral portion 22 of the light-outcoupling layer 2, it is also possible to more inhibit the intrusion of moisture at the outside of the sealed region. Consequently, it is possible to form a structure allowing more inhibiting the intrusion of moisture.

In the present embodiment, the light-outcoupling layer 2 is separated into the central portion 21 and the peripheral portion 22, and hence an electrode connector 12 is provided as a portion electrically connecting the extension electrode 11 to inward electrodes. In other words, the organic EL element 100A includes the electrode connector 12 electrically connecting the light-emitting layer 10 to the extension electrode 11. The electrode connector 12 is formed to extend across the groove 20 along an internal surface of the groove 20. In summary, the electrode connector 12 is formed on the internal surface of the groove 20. Especially, the electrode connector 12 is formed on the entire internal surface of the groove 20. Particularly, the electrode connector 12 covers the entire side surface 201 of the peripheral portion 22 so that the side surface 201 of the peripheral portion 22 is not exposed to the sealed region (sealed space) enclosed by the light transmissive substrate 1, the sealing base 6, and the sealing bond 7.

The electrode connector 12 includes at least one first electrode connector 12a electrically connecting the first electrode 3 to the first extension electrode 11a and at least one second electrode connector 12b electrically connecting the second electrode 5 to the second extension electrode 11b.

In summary, the first electrode 3 and the first extension electrode 11a are electrically connected to each other by the first electrode connector 12a formed across a gap between the central portion 21 and the peripheral portion 22 (first peripheral portion 22a) of the light-outcoupling layer 2. Similarly, the second electrode 5 and the second extension electrode 11b are electrically connected to each other by the second electrode connector 12b formed across a gap between the central portion 21 and the peripheral portion 22 (second peripheral portion 22b) of the light-outcoupling layer 2. By forming the electrode connector 12, electric conduction between the extension electrode 11 and the electrodes is secured. The electrode connector 12 may be made of electrically conductive material.

As shown in FIG. 1(b), the first electrode connector 12a is formed to make connection between the first extension electrode 11a formed on the surface of the first peripheral portion 22a of the light-outcoupling layer 2 and the first electrode 3 formed on the central portion 21 of the light-outcoupling layer 2. Thus, electric conduction between the first electrode 3 and the first extension electrode 11a is enabled.

The second electrode connector 12b is a part extending from the second electrode 5 toward the second extension electrode 11b. In other words, the second electrode connector 12b is formed integrally with the second electrode 5. Hence, it is possible to form the second electrode connector 12b with a simplified structure. Therefore, in contrast to a case where the second electrode connector 12b is made of material different from material of the second electrode 5, it is possible to omit a step of forming an additional layer for the second electrode connector 12b, and thus the manufacture can be facilitated. When the second electrode connector 12b is a part extended from the second electrode 5, the second electrode connector 12b can be formed easily, and thus the second extension electrode 11b and the second electrode 5 can be electrically connected to each other.

Further in the present embodiment, it is preferable that the first electrode connector 12a be formed of a layer which is made of the same material as the second electrode 5 but is separate from the second electrode 5. In other words, the first electrode connector 12a is formed of a part separated from an electrically conductive layer to be a base of the second electrode 5. Consequently, it is possible to form the first electrode connector 12a with a simplified structure. Therefore, in contrast to a case where the first electrode connector 12a is made of material different from material of the second electrode 5, it is possible to omit a step of forming an additional layer for the first electrode connector 12a, and thus the manufacture can be facilitated.

When the first electrode connector 12a is made of the same material as the second electrode 5, the first electrode connector 12a can be formed at the same time of forming the second electrode 5. Therefore, the first electrode connector 12a can be easily formed and thus the first extension electrode 11a and the first electrode 3 can be electrically connected to each other.

In a case where layers for the first electrode connector 12a and the second electrode connector 12b are formed at the same time of forming a layer for the second electrode 5, there is no need to perform a step of forming a layer for the electrode connector 12, and thus the electrode connector 12 can be formed efficiently. The first electrode connector 12a may be made of Al or Ag, for example.

In this regard, the electrically conductive layer for forming the first electrode 3 is an electrically conductive layer with light transmissive properties and relatively high electric resistance. However, when the electrode connector 12 is made of material having electric resistance lower than electric resistance of the electrically conductive layer for forming the first electrode 3, the electrode connector 12 can enhance electric conduction in the electrically conductive layer for forming the first electrode 3, and thus electric conductivity can be improved.

Additionally, the electrode connector 12 is formed outside a light emission region (region in which the first electrode 3, the organic layer 4, and the second electrode 5 are stacked), and hence the electrode connector 12 need not be transparent. Therefore, the electrode connector 12 may be made of an appropriate metal layer, and accordingly it is possible to form the element with high electric conductivity.

For example, normally, material of the first electrode 3 is lower in electric resistance than material of the second electrode 5. Hence, when the electrode connector 12 is made of the material of the second electrode 5, the electric conductivity can be easily improved. Alternatively, the electrode connector 12 may be made of material higher in electric conductivity than the material of the second electrode 5. When the electric conductivity of the electrically conductive layer for forming the first electrode 3 is improved, uniformity of in-plane light emission can be improved.

In the present embodiment, as shown in FIG. 1(a) and FIG. 1(b), the electrode connector 12 is formed to cover the extension electrode 11 on the surface (upper surface in FIG. 1(b)) of the peripheral portion 22 of the light-outcoupling layer 2 with regard to the inside of the sealed region. Hence, inside the sealed region, the side surface (end surface resulting from separation) of the peripheral portion 22 of the light-outcoupling layer 2 is covered with the electrode connector 12.

As described above, by covering the side surface 201 of the peripheral portion 22 of the light-outcoupling layer 2, intrusion of moisture into the inside through the light-outcoupling layer 2 can be more inhibited. Note that, it is preferable that the electrode connector 12 be made of material with moisture permeability lower than moisture permeability of the light-outcoupling layer 2. Generally, when the electrode connector 12 is made of electrode material, the electrode connector 12 can have moisture permeability lower than the moisture permeability of the light-outcoupling layer 2.

In the present embodiment, the central portion (first portion) 21 and the peripheral portion (second portion) 22 of the light-outcoupling layer 2 are separated, and thus the recess (groove) 20 is formed in-between. In this case, it is preferable that the side surfaces 201 of the recess 20 of the light-outcoupling layer 2 be inclined surfaces. In other words, at least one of both side faces of the recess (groove) 20 is an inclined surface that is inclined from the surface 1a of the substrate 1. When the side surfaces 201 of the recess 20 are inclined surfaces, it is possible to inhibit division of the electrode connector 12 which would otherwise occur due to cutting by edges in formation of the electrode connector 12 extending across the recess 20. Consequently, the electrode connector 12 with high electric conductivity can be formed.

When the side surface (an end surface of the light-outcoupling layer 2 resulting from separation) 201 of the recess (groove) 20 is inclined, an angle of inclination of the side surface 201 of the recess 20 is represented as an inclined angle θ as shown in FIG. 1(b). The inclined angle θ is defined as an angle of the end surface (side surface) 201 resulting from separation relative to the surface 1a of the light-outcoupling layer 2 facing the light transmissive substrate 1.

It is sufficient that the inclined angle θ is less than 90 degrees. The inclined angle θ is allowed to be less than 80 degrees, 70 degrees, or 60 degrees. The formation of the electrode connector 12 without causing division of the electrode connector 12 due to cutting by edges become easier as the inclined angle θ is smaller.

Whereas, when the inclined angle θ is too small, the side surface of the recess 20 almost lies, and thus the length of this side surface is likely to become too long. Hence, the inclined angle θ may be equal to or more an appropriate angle such as 30 degrees, 45 degrees, and 60 degrees.

Note that, the side surface of the recess 20 may be a curved surface which is curved inward or outward. When the side surface of the recess 20 is the curved surface, the incline angle θ may be considered as an angle of a straight line interconnecting an upper edge and a lower edge of the side surface to the surface of the light-outcoupling layer 2 facing the light transmissive substrate 1.

In the present embodiment, it is preferable that a total thickness of the extension electrode 11 and the sealing bond 7 at a position where the extension electrode 11 is formed be equal to or more than the thickness of the light-emitting stack 10. That is, a total of the thickness of the extension electrode 11 and the thickness of a portion of the sealing bond 7 positioned on this extension electrode 11 is greater than the thickness of the light-emitting layer 10. In other words, it is preferable that the total of the thicknesses of the peripheral portion 22 of the light-outcoupling layer 2, the extension electrode 11, and the sealing bond 7 be equal to or more than the total of the thicknesses of the central portion 21 of the light-outcoupling layer 2, the first electrode 3, the organic layer 4, and the second electrode 5.

By doing so, the light-emitting stack 10 can be easily enclosed by use of the sealing base 6 in a flat plate shape having a surface to be used for sealing that is made flat. In the sealing bond 7, a thickness at a position where the light-outcoupling layer 2 is provided is different from a thickness at a position where the light-outcoupling layer 2 is not provided. Hence, the thickness of the sealing bond 7 is determined on the basis of the position where the light-outcoupling layer 2 is provided.

Note that, a thickest portion in the sealing bond 7 has a thickness equal to the distance between the light transmissive substrate 1 and the sealing base 6. The thickness of the sealing bond 7 at the thickest portion may be selected to be equal to or more than the total of the thicknesses of the central portion 21 of the light-outcoupling layer 2, the first electrode 3, the organic layer 4, and the second electrode 5. Normally, in the light-outcoupling layer 2, the central portion 21 and the peripheral portion 22 have the same thickness. The extension electrode 11 (the first extension electrode 11a and the second extension electrode 11b) and the first electrode 3 have the same thickness. In view of this, the thickness of the sealing bond 7 at the position where the extension electrode 11 is formed may be selected to be equal to or more than the total of the thicknesses of the organic layer 4 and the second electrode 5.

The sealing bond 7 may serve as a spacer to keep a clearance corresponding to the thickness of the light-emitting stack 10 in sealing by the sealing base 6. When the sealing bond 7 serving as the spacer is used, in contrast to an example where the recess for accommodating the light-emitting stack 10 is provided to the sealing base 6 by excavating a glass substrate for the sealing base 6, the production can become easy and the production cost can be lowered. Further, when the thickness of the sealing bond 7 is equal to the thickness as described above, the sealing bond 7 becomes tall, and thus the surface, facing the sealing base 6, of the sealing bond 7 is closer to the outside than the surface, facing the sealing base 6, of the light-emitting stack 10 is. Consequently, in the sealing, the sealing base 6 can be bonded at its flat surface.

In one possible example, the light-outcoupling layer 2 does not extend to the peripheral portion of the substrate 1, and instead the sealing bond 7 is formed on the entire peripheral portion of the substrate 1. In this example, the sealing bond 7 tends to have an excessive thickness, and this is likely to cause a significant increase in an amount of moisture intruding through the sealing bond 7. In this regard, to improve sealing properties, it is necessary to excavate the sealing base 6 to form therein an accommodation recess for accommodating the light-emitting stack 10 together with the light-outcoupling layer 2.

In the present embodiment, the light-outcoupling layer 2 is made extend to the peripheral portion of the light transmissive substrate 1, and the sealing bond 7 is formed on the surface of the portion, on the peripheral portion of the light transmissive substrate 1, of the light-outcoupling layer 2. In other words, the peripheral portion 22 serves as part of a spacer.

Therefore, it can be prevented that the sealing bond 7 becomes too thick. Further, the sealing can be conducted by use of the sealing base 6 with the flat surface. Thus, it can be easy to produce the element capable of prevention of moisture intrusion. Additionally, in contrast to a case where the sealing base 6 is excavated, the production becomes easy, and the production cost can be lowered.

The first embodiment shown in FIG. 1 includes a configuration in which the first extension electrode 11a and the second extension electrode 11b are formed of the electrically conductive layer for forming the first electrode 3. However, the first to fifth embodiments in accordance with the present invention need not include this configuration necessarily. For example, the first extension electrode 11a and the second extension electrode 11b may be made of electrically conductive material different from the electrically conductive layer for forming the first electrode 3.

As described above, the organic electroluminescence element 100A of the present embodiment is an organic electroluminescence element in which the light-emitting stack 10 is provided to the surface 2a of the light-outcoupling layer 2 provided to the surface 1a of the light transmissive substrate 1, and the light-emitting stack 10 includes the first electrode 3 with light transmissive properties, the organic layer 4, and the second electrode 5 that are arranged in this order from the light transmissive substrate 1. The sealing base 6 facing the light transmissive substrate 1 is bonded to the light transmissive substrate 1 with the sealing bond 7 surrounding the periphery of the light-emitting stack 10. The extension electrode 11 which extends from the inside to the outside of the sealed region in which the light-emitting stack 10 is enclosed by use of the sealing base 6 is formed on the surface 2a of the light-outcoupling layer 2. The light-outcoupling layer 2 is separated into the central portion 21 where the light-emitting stack 10 is formed and the peripheral portion 22 where the sealing bond 7 is formed.

In other words, the organic EL element 100A of the present embodiment includes the following first and second features. Note that the second feature is optional.

According to the first feature, the organic EL element 100A includes: the substrate 1; the light-outcoupling layer 2 situated on the surface 1a of the substrate 1; the light-emitting layer 10 situated on the face 2a on the opposite side of the light-outcoupling layer 2 from the substrate 1; the sealing base 6 situated facing the face 2a of the light-outcoupling layer 2; and the sealing bond 7 formed to enclose the light-emitting layer 10 and bond the sealing base 6 to the face 2a of the light-outcoupling layer 2. The light-outcoupling layer 2 includes: the first portion (central portion) 21 where the light-emitting layer 10 is situated; the second portion (peripheral portion) 22 where the sealing bond 7 is situated; and the groove (recess) 20 spatially separating the first portion 21 from the second portion 22.

According to the second feature referring to the first feature, the organic EL element 100A includes the extension electrode 11 electrically connected to the light-emitting layer 10. The extension electrode 11 is situated between the face 2a of the light-outcoupling layer 2 and the sealing bond 7 so as to extend across the sealing bond 7.

Additionally, in the organic EL element 100A of the present embodiment, at least inside the sealed region the surface of the peripheral portion 22 of the light-outcoupling layer 2 is covered with the extension electrode 11.

In other words, the organic EL element 100A of the present embodiment includes the following third feature. Note that the third feature is optional. According to the third feature referring to the second feature, the extension electrode 11 is formed to cover the second portion 22.

Additionally, in the organic EL element 100A of the present embodiment, the extension electrode 11 includes the first extension electrode 11a electrically connected to the first electrode 3 and the second extension electrode 11b electrically connected to the second electrode 5. The first electrode 3 and the first extension electrode 11a are interconnected by the first electrode connector 12a extending across the gap between the central portion 21 and the peripheral portion 22 of the light-outcoupling layer 2. The second electrode 5 and the second extension electrode 11b are interconnected by the second electrode connector 12b extending across the gap between the central portion 21 and the peripheral portion 22 of the light-outcoupling layer 2. The second electrode connector 12b is a part extending from the second electrode 5 to the second extension electrode 11b.

In other words, the organic EL element 100A of the present embodiment includes the following fourth and fifth features. Note that the fourth and fifth features are optional.

According to the fourth feature referring to the second or third feature, the organic EL element 100 includes the electrode connector 12 electrically connecting the light-emitting layer 10 to the extension electrode 11. The electrode connector 12 is formed to extend across the groove 20 along the internal surface (201a, 1a, and 201b) of the groove 20.

According to the fifth feature referring to the fourth feature, the light-emitting layer 10 includes: the first electrode 3 situated on the face 2a of the light-outcoupling layer 2; the second electrode 5 situated facing the face on the opposite side of the first electrode 3 from the light-outcoupling layer 2; and the organic layer 4 interposed between the first electrode 3 and the second electrode 5 and configured to emit light in response to application of a voltage between the first electrode 3 and the second electrode 5. The extension electrode 11 includes the first extension electrode 11a and the second extension electrode 11b. The electrode connector 12 includes the first electrode connector 12a electrically connecting the first electrode 3 to the first extension electrode 11a and the second electrode connector 12b electrically connecting the second electrode 5 to the second extension electrode 11b. The second electrode connector 12b is formed integrally with the second electrode 5.

Additionally, in the organic EL element 100A of the present embodiment, the first electrode connector 12a is formed of one or more layers which are made of the same material as the second electrode 5 but is separated from the second electrode 5.

In other words, the organic EL element 100A of the present embodiment includes the following sixth feature. Note that the sixth feature is optional. According to the sixth feature referring to the fifth feature, the first electrode connector 12a is formed of a part separated from the electrically conductive layer to be a base of the second electrode 5.

Additionally, in the organic EL element 100A of the present embodiment, the side surface 201 of the recess 20 formed as a result of separation of the light-outcoupling layer 2 into the central portion 21 and the peripheral portion 22 is an inclined surface.

In other words, the organic EL element 100A of the present embodiment includes the following seventh feature. Note that the seventh feature is optional. According to the seventh feature referring to any one of the first to sixth features, at least one of both side faces 201 of the groove 20 is an inclined surface that is inclined from the surface 1a of the substrate 1.

Additionally, in the organic EL element 100A of the present embodiment, the gap which is between the light transmissive substrate 1 and the sealing base 6 and accommodates the light-emitting stack 10 is filled with the filler.

In other words, the organic EL element 100A of the present embodiment includes the following eighth and ninth features. Note that the eighth and ninth features are optional. According to the eighth feature referring to any one of the first to seventh features, the organic EL element 100A includes the protector 80 protecting the light-emitting layer 10. The protector 80 is formed by filling with filler 8 the space enclosed by the substrate 1, the sealing base 6, and the sealing bond 7.

According to the ninth feature referring to the eighth feature, the filler 8 contains a hygroscopic agent.

Additionally, in the organic EL element 100A of the present embodiment, the total thickness of the extension electrode 11 and the sealing bond 7 at the position where the extension electrode 11 is formed is equal to or more than the thickness of the light-emitting stack.

In other words, the organic EL element 100A of the present embodiment includes the following tenth feature. Note that the tenth feature is optional. According to the tenth feature referring to any one of the second to ninth features, the total of the thickness of the extension electrode 11 and the thickness of the portion of the sealing bond 7 positioned on this extension electrode 11 is greater than the thickness of the light-emitting layer 10.

Additionally, the organic EL element 100A of the present embodiment includes the following eleventh to thirteenth features. Note that the eleventh to thirteenth features are optional.

According to the eleventh feature referring to any one of the first to tenth features, the substrate 1 is made to transmit light emitted from the light-emitting layer 10.

According to the twelfth feature referring to the eleventh feature, the light-outcoupling layer 2 includes at least one of the light refraction layer 23 and the light scattering layer 9. The light refraction layer 23 is a layer having the refractive index between the refractive index of the portion (the first electrode 3 in the present embodiment) of the light-emitting layer 10 that is in contact with the light-outcoupling layer 2 and the refractive index of the substrate 1. The light scattering layer 9 is a layer having the structure causing scattering of light emitted from the light-emitting layer 10.

According to the thirteenth feature referring to any one of the first to twelfth features, the substrate 1 and the sealing base 6 are made of moisture proof material.

### Second Embodiment

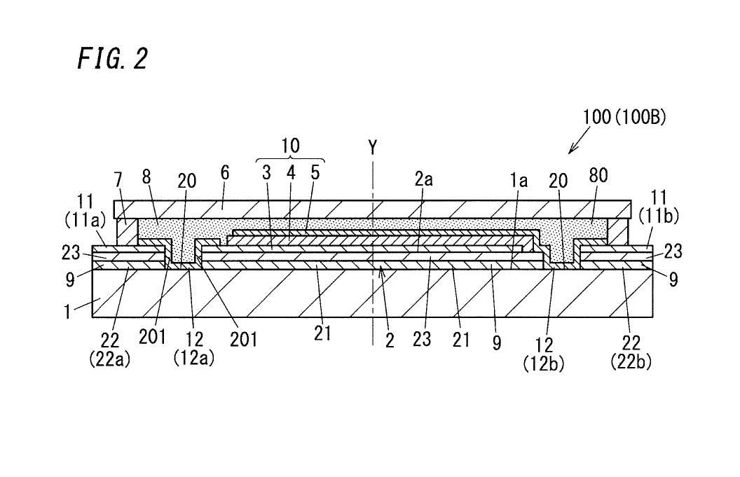

FIG. 2 shows another embodiment of the organic EL element, and this embodiment has a planar view same as that shown in FIG. 1(a).

The organic EL element 100 (100B) of the present embodiment has the same structure as the first embodiment shown in FIG. 1 except that the side surface 201 of the recess 20 of the light-outcoupling layer 2 is a surface perpendicular to the surface 1a of the light transmissive substrate 1. Hence, also the organic EL element according to the second embodiment can have a superior light-outcoupling efficiency and yet can inhibit moisture intrusion efficiently and thus is highly reliable and is less likely to deteriorate.

Normally, when the side surface of the recess 20 is a perpendicular surface and the light-outcoupling layer 2 and/or the electrically conductive layer for forming the first electrode 3 become thick, cutting by edges may occur around the part of the electrode connector 12 on the perpendicular surface and thus the electrode connector 12 may be divided. For example, when a layer for the electrode connector 12 is formed, such a layer may be cut due to level differences caused by separation of the light-outcoupling layer 2 and therefore the electrode connector 12 may be divided.

In contrast, when the side surface 201 of the recess 20 of the light-outcoupling layer 2 is the inclined surface like the first embodiment shown in FIG. 1, in a step of forming a layer for the electrode connector 12, a layer of material of the electrode connector 12 is formed so as to extend from the surface of the light-outcoupling layer 2 to the surface of the substrate 1 across the inclined surface which defines a border between the surface of the light-outcoupling layer 2 and the surface of the light transmissive substrate 1. Consequently, such a layer can be formed without suffering from cutting by edges, and thus the electrode connector 12 can be formed more successfully.

Whereas, in the second embodiment of FIG. 2, it is sufficient that the light-outcoupling layer 2 is separated by cutting the light-outcoupling layer 2 vertically. Hence, there is an advantage that the recess 20 can be formed by separating the light-outcoupling layer 2 easily.

In summary, the organic EL element 100B of the present embodiment includes the following fourteenth feature instead of the above seventh feature. According to the fourteenth feature, at least one of both side faces 201 of the groove 20 is a surface perpendicular to the surface 1a of the substrate 1.

### Third Embodiment

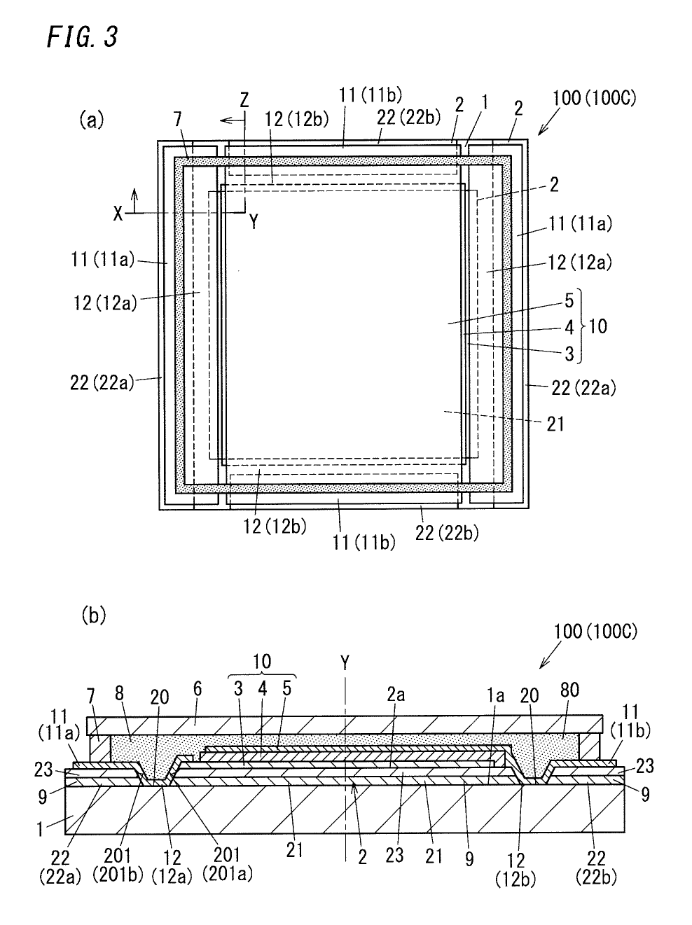

FIG. 3 shows another embodiment of the organic EL element. The organic EL element 100 (100C) of the present embodiment has the same structure as the first embodiment shown in FIG. 1 except the structure of the extension electrode 11 situated on the periphery of the light-outcoupling layer 2.

In more detail, in the third embodiment, the light-emitting stack 10 is provided to the surface 2a of the light-outcoupling layer 2 provided to the surface 1a of the light transmissive substrate 1, and includes the first electrode 3 with light transmissive properties, the organic layer 4, and the second electrode 5 which are arranged in this order from the light transmissive substrate 1.

Additionally, the sealing base 6 facing the light transmissive substrate 1 is bonded to the light transmissive substrate 1 with the sealing bond 7 surrounding the periphery of the light-emitting stack 10.

Additionally, the extension electrode 11 which extends from the inside to the outside of the sealed region in which the light-emitting stack 10 is enclosed by use of the sealing base 6 is provided to the surface 2a of the light-outcoupling layer 2.

Additionally, the light-outcoupling layer 2 is separated into the central portion 21 where the light-emitting stack 10 is formed and the peripheral portion 22 where the sealing bond 7 is formed.

Additionally, the side surface of the recess 20 formed as a result of separation of the light-outcoupling layer 2 into the central portion 21 and the peripheral portion 22 is an inclined surface. Further, the gap which is between the light transmissive substrate 1 and the sealing base 6 is filled with the filler 8.

However, in the present embodiment, the electrically conductive layer for forming the first electrode 3 is not formed on the surface (upper surface in FIG. 3(b)) of the peripheral portion 22 of the light-outcoupling layer 2.

The peripheral portion 22 of the light-outcoupling layer 2 is divided into the first peripheral portion (first side) 22a and the second peripheral portion (second side) 22b.

The first extension electrode 11a is formed on the surface (upper surface in FIG. 3(b)) of the first peripheral portion 22a, and the first extension electrode 11a is formed of a portion extended toward outside from the first electrode connector 12a and thus formed integrally with the first electrode connector 12a. The layer (layer forming the first extension electrode 11a and the first electrode connector 12a) may be a layer which is made of the same material as the second electrode 5 but is separate from the second electrode 5. In this case, the first electrode connector 12a and the first extension electrode 11a can be formed easily.

The second extension electrode 11b is formed on the surface (upper surface in FIG. 3(b)) of the second peripheral portion 22b of the light-outcoupling layer 2, and the second extension electrode 11b is formed of a portion extended toward outside from the second electrode connector 12b which is a portion extended from the second electrode 5.

In summary, in the present embodiment, the part which is extended from a side, close to the inside of the element, of the first extension electrode 11a constitutes the first electrode connector 12a. Further, the part which is protruded from the second electrode 5 so as to extend from the inside to the outside of the sealed region constitutes the second electrode connector 12b and the second extension electrode 11b.

In summary, the organic EL element 100C of the present embodiment includes the following fifteenth and sixteenth features. According to the fifteenth feature referring to any one of the first to fourteenth features, the first extension electrode 11a is formed integrally with the first electrode connector 12a. According to the sixteenth feature referring to any one of the first to fifteenth features, the second extension electrode 11b is formed integrally with the second electrode connector 12b.

In this structure, the extension electrode 11 can be easily formed by extending the electrically conductive layer from the inside to the outside of the sealed region.

In the present embodiment, the surface (upper surface in FIG. 3(b)) of the peripheral portion 22 of the light-outcoupling layer 2 is covered with the extension electrode 11 which is formed integrally with the electrode connector 12 and defined by the part extended from the inside to the outside of the sealed region. Therefore, it is possible to successfully prevent intrusion of moisture into the inside of the element. The layer defining the electrode connector 12 and the extension electrode 11 integrally formed covers the side surface of the peripheral portion 22 of the light-outcoupling layer 2, and thus moisture intrusion can be more inhibited.

The third embodiment of FIG. 3 is superior to the first embodiment of FIG. 1 in the following points: the process of patterning the electrodes may be easier in the third embodiment than in the first embodiment; and the electric conductivity may be more improved in the third embodiment than in the first embodiment. In the case where the material of the extended extension electrode 11 tends to allow moisture intrusion, the first embodiment of FIG. 1 in which the sealing bond 7 is provided to the surface of the electrically conductive layer for forming the first electrode 3 is preferable.

### Fourth Embodiment

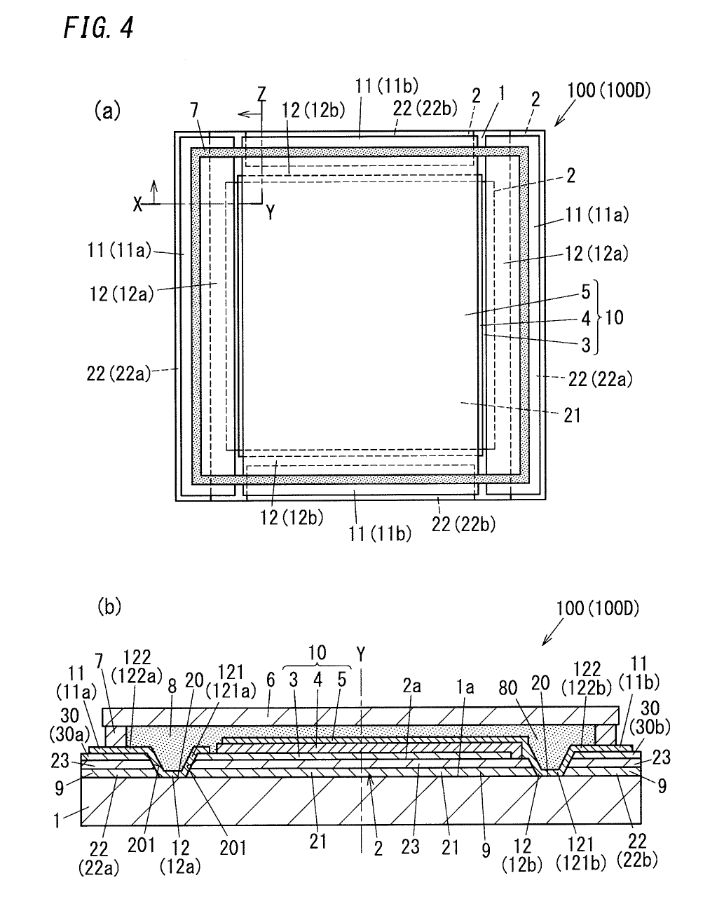

FIG. 4 shows another embodiment of the organic EL element. The organic EL element 100 (100D) of the present embodiment has the same structure as the first embodiment shown in FIG. 1 and the third embodiment shown in FIG. 3 except the structure of the extension electrode 11 situated on the periphery of the light-outcoupling layer 2.

In more detail, in the fourth embodiment, the light-emitting stack 10 is provided to the surface 2a of the light-outcoupling layer 2 provided to the surface 1a of the light transmissive substrate 1, and includes the first electrode 3 with light transmissive properties, the organic layer 4, and the second electrode 5 which are arranged in this order from the light transmissive substrate 1.

Additionally, the sealing base 6 facing the light transmissive substrate 1 is bonded to the light transmissive substrate 1 with the sealing bond 7 surrounding the periphery of the light-emitting stack 10.

Additionally, the extension electrode 11 which extends from the inside to the outside of the sealed region in which the light-emitting stack 10 is enclosed by use of the sealing base 6 is provided to the surface 2a of the light-outcoupling layer 2.

Additionally, the light-outcoupling layer 2 is separated into the central portion 21 where the light-emitting stack 10 is formed and the peripheral portion 22 where the sealing bond 7 is formed.

Additionally, the side surface 201 of the recess 20 formed as a result of separation of the light-outcoupling layer 2 into the central portion 21 and the peripheral portion 22 is an inclined surface. Further, the gap which is between the light transmissive substrate 1 and the sealing base 6 is filled with the filler 8.

In the present embodiment, the electrically conductive layer for forming the first electrode 3 includes a part formed on the surface (upper surface in FIG. 4(b)) of the peripheral portion 22 of the light-outcoupling layer 2, and a layer extending outward from the electrode connector 12 is formed on the surface of the part of the electrically conductive layer.

The peripheral portion 22 of the light-outcoupling layer 2 is divided into the first peripheral portion (first side) 22a and the second peripheral portion (second side) 22b.

In this regard, on the surface (upper surface in FIG. 3(b)) of the first peripheral portion 22a, a part of the electrically conductive layer and a part extended from the first electrode connector 12a are stacked, and this stack forms the first extension electrode 11a.

In more detail, the organic EL element 100D includes an electrode layer 30 (30a) formed on an opposite side of the first peripheral portion (second portion) 22a of the light-outcoupling layer 2 from the substrate 1. The electrode layer 30a is formed of a part separated from the electrically conductive layer serving as the base for the first electrode 3. The first electrode connector 12a includes a connection part 121 (121a) and an extension part 122 (122a) which are formed integrally. The connection part 121 (121a) is positioned in the recess (groove) 20 (20a). The extension part 122 (122a) is positioned on an opposite side of the electrode layer 30a from the light-outcoupling layer 2. The first extension electrode 11a is constituted by the electrode layer 30a and the extension part 122a.

The first electrode connector 12a may be a member which is made of the same material as the second electrode 5 and separate from the second electrode 5. In this case, the first electrode connector 12a and the first extension electrode 11a can be formed easily.

Additionally, on the surface (upper surface in FIG. 3(b)) of the second peripheral portion 22b of the light-outcoupling layer 2, a part of the electrically conductive layer and a part extended from the second electrode connector 12b which is a portion extended from the second electrode 5 are stacked, and this stack forms the second extension electrode 11b.

In more detail, the organic EL element 100D includes an electrode layer 30 (30b) formed on an opposite side of the second peripheral portion (second portion) 22b of the light-outcoupling layer 2 from the substrate 1. The electrode layer 30b is formed of a part separated from the electrically conductive layer serving as the base for the first electrode 3. The second electrode connector 12b includes a connection part 121 (121b) and an extension part 122 (122b) which are formed integrally. The connection part 121 (121b) is positioned in the recess (groove) 20 (20b). The extension part 122 (122b) is positioned on an opposite side of the electrode layer 30b from the light-outcoupling layer 2. The second extension electrode 11b is constituted by the electrode layer 30b and the extension part 122b.

In summary, the organic EL element 100D of the present embodiment includes the following seventeenth feature. According to the seventeenth feature, the organic EL element 100D includes the electrode layer 30 formed on the opposite side of the peripheral portion (second portion) 22 of the light-outcoupling layer 2 from the substrate 1. The electrode layer 30 is formed of part separated from the electrically conductive layer serving as the base for the first electrode. The electrode connector 12 includes the connection part 121 and the extension part 122 which are formed integrally, the connection part 121 being positioned in the recess (groove) 20 and the extension part 122 being positioned on the opposite side of the electrode layer 30 from the light-outcoupling layer 2. The extension electrode 11 is constituted by the electrode layer 30 and the extension part 122.

In this structure, the extension electrode 11 can be easily formed by extending the electrically conductive layer from the inside to the outside of the sealed region.

In the present embodiment, inside the sealed region, the surface (upper surface in FIG. 4(b)) of the peripheral portion 22 of the light-outcoupling layer 2 is covered with the extension electrode 11 which is a stack of the electrically conductive layer (electrode layer 30) for forming the first electrode 3 and the extended part (extension part 122) of the electrode connector 12. Therefore, it is possible to greatly inhibit intrusion of moisture into the inside of the element. Additionally, the electrode connector 12 covers the side surface of the peripheral portion 22 of the light-outcoupling layer 2 and thus moisture intrusion can be more inhibited.

The fourth embodiment of FIG. 4 is superior to the first embodiment of FIG. 1 in that the electric conductivity is potentially improved. However, when the layer forming the electrode connector 12 tends to allow moisture intrusion, the first embodiment of FIG. 1 in which the electrode connector 12 is formed within the inside of the sealed region the first electrode 3 is preferable.

As apparent from the third embodiment of FIG. 3 and the fourth embodiment of FIG. 4, the extension electrode 11 of the organic EL element 100 (100C, 100D) may be made of appropriate material.

For example, the first extension electrode 11a and the second extension electrode 11b may be made of different electrically conductive material from the electrically conductive layer for forming the first electrode 3. In this case, the first extension electrode 11a and the second extension electrode 11b can be lower in electric resistance than the electrically conductive layer for forming the first electrode 3. For example, the first extension electrode 11a and the second extension electrode 11b preferably have low electric resistance, and hence may be made of a metal layer of aluminum, copper, molybdenum, or the like.

In this regard, the third embodiment of FIG. 3 shows an example in which the first extension electrode 11a and the second extension electrode 11b are made of the same material as the second electrode 5. Note that, the first extension electrode 11a and the second extension electrode 11b may be made of different material from the first electrode 3. In this case, the first extension electrode 11a and the second extension electrode 11b need not be transparent because the first extension electrode 11a and the second extension electrode 11b are formed on the peripheral portion of the substrate.

Note that, in the third embodiment shown in FIG. 3, the first extension electrode 11a and the second extension electrode 11b both are made of different electrically conductive material from the electrically conductive layer for forming the first electrode 3, however the first extension electrode 11a and the second extension electrode 11b are not limited to such a structure.

In other words, either the first extension electrode 11a or the second extension electrode 11b may be made of different electrically conductive material (e.g., the same material of the second electrode 5) from the electrically conductive layer for forming the first electrode 3. In this case, one extension electrode 11 may have the same structure as that of the third embodiment shown in FIG. 3, and the other extension electrode 11 may have the same structure as that of the first embodiment shown in FIG. 1.

Alternatively, as shown in the fourth embodiment of FIG. 4, the extension electrode 11 may be a stack of the electrically conductive layer for forming the first electrode 3 and the layer extended from the electrode connector 12. In this regard, when the electrically conductive layer for forming the first electrode 3 has relatively high electric resistance, by providing the layer of the electrode connector 12, the electric conduction in the electrically conductive layer can be enhanced. Alternatively, one extension electrode 11 may have the same structure as that of the fourth embodiment shown in FIG. 4, and the other extension electrode 11 may have the same structure as that of the first embodiment shown in FIG. 1 or the third embodiment shown in FIG. 3.

### Fifth Embodiment

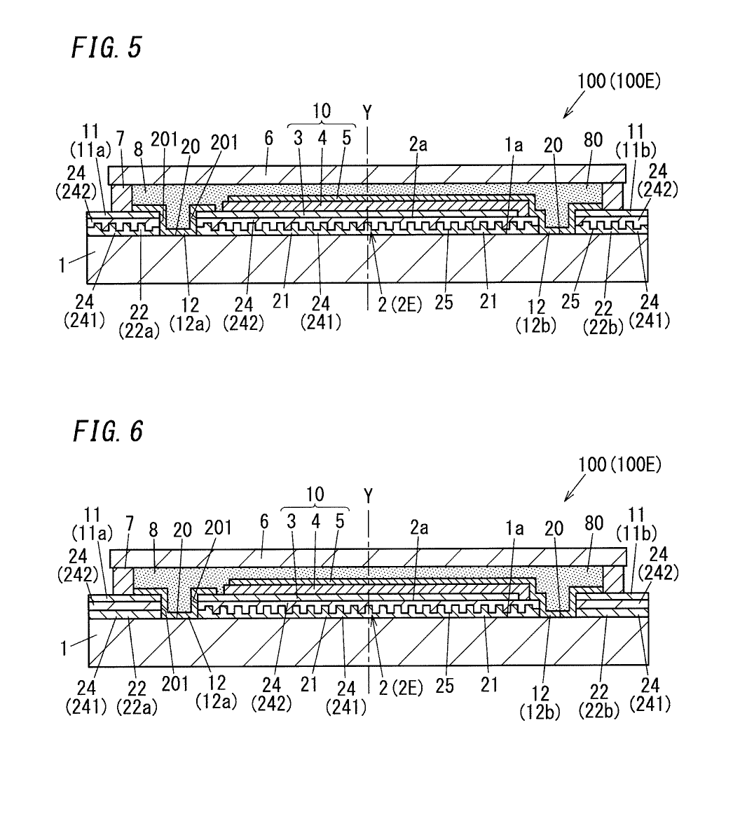

FIG. 5 shows another embodiment of the organic EL element, and this embodiment is also illustrated by the planar view shown in FIG. 1(a).

The organic EL element 100 (100E) of the present embodiment is different from the second embodiment shown in FIG. 2 in the structure of the light-outcoupling layer 2 (2E). Note that, components common to the present embodiment and the second embodiment are designated by the same reference sings, and explanations thereof are deemed unnecessary.

The light-outcoupling layer 2E is constituted by a plurality of (two in the illustrated example) of light transmissive layers 24 (241 and 242). The plurality of light transmissive layers 24 are stacked in the thickness direction of the substrate 1. Additionally, each of the light transmissive layers 24 is made to transmit light from the light-emitting stack 10.

For example, the light-outcoupling layer 2 includes the light transmissive layer (first light transmissive layer) 241 formed on the surface 1a of the substrate 1 and the light transmissive layer (second light transmissive layer) 242 formed on an opposite side of the first light transmissive layer 241 from the substrate 1.

The light-outcoupling layer 2E includes a diffraction structure 25 at an interface between the plurality of light transmissive layers 24. The diffraction structure 25 causes diffraction of light (light from the light-emitting stack 10). The light-outcoupling layer 2E includes the diffraction structure 25 and thus can scatter light. The diffraction structure 25 may be an appropriate uneven structure. The uneven structure may be a structure in fine protrusions are arranged in a plane, for example. These protrusions may have a shape of hemisphere, pleat, pyramid (quadrangular pyramid), frustum, or the like. In this regard, the protrusions may be arranged regularly or irregularly.

For example, the light-outcoupling layer 2E can be formed as follows. First, the first light transmissive layer 241 is formed on the surface 1a of the substrate 1. Next, the diffraction structure 25 is formed on/in the surface on the opposite side of the first light transmissive layer 241 from the light transmissive substrate 1. Subsequently, the second light transmissive layer 242 is formed on the diffraction structure 25 formed on/in the first light transmissive layer 241. Note that, the diffraction structure 25 may be formed by imprinting, for example.

The organic EL element 100E of the present embodiment described above includes the following eighteenth feature. According to the eighteenth feature, the light-outcoupling layer 2E includes the plurality of light transmissive layers 24 stacked in the thickness direction of the substrate 1. The light-outcoupling layer 2E includes the diffraction structure 25 diffracting light (light from the light-emitting layer 10) at an interface between the plurality of light transmissive layers 24.

According to the present embodiment, the light-outcoupling layer 2 (2E) has a function of scattering light. Therefore, light traveling toward the light transmissive substrate 1 is scattered by the light-outcoupling layer 2E, and thus total reflection is suppressed. Consequently, a larger amount of light can emerge outside.

Note that, the light-outcoupling layer 2E may have at least one of the diffraction structures at the both surfaces of the light-outcoupling layer 2E. For example, the diffraction structure 25 may be provided to the surface of the light-outcoupling layer 2 facing the substrate 1, or the diffraction structure 25 may be provided to the face (surface) 2a on the opposite side of the light-outcoupling layer 2 from the substrate 1.

Note that, each light transmissive layer 24 may have a refractive index between the refractive indices of the first electrode 3 and the substrate 1. In this case, total reflection of light emitted from the light-emitting layer 10, which would occur between the light-emitting layer 10 and the substrate 1, can be suppressed more efficiently.

In the light-outcoupling layer 2E, as shown in FIG. 5, each of the first portion (central portion) 21 and the second portion (peripheral portion) 22 has the diffraction structure 25. The second portion (peripheral portion) 22 is not positioned in a path of light from the light-emitting layer 10. Hence, there is no need to always provide the diffraction structure 25 to the second portion 22.

For example, in the light-outcoupling layer 2E, as shown in FIG. 6, the diffraction structure 25 may be provided to only the first portion (central portion) 21.

When the light-outcoupling layer 2E has a relatively large size, it is possible to easily provide the diffraction structure 25 also to the peripheral portion 22 by imprinting. However, when the light-outcoupling layer 2E has a relatively small size, it is difficult to provide the diffraction structure 25 to the peripheral portion 22 by imprinting in some cases. In those cases, as shown in FIG. 6, the diffraction structure 25 may be provided to only the central portion 21 of the light-outcoupling layer 2E by imprinting, but may be not provided to the peripheral portion 22 by imprinting.

### (Production Method)

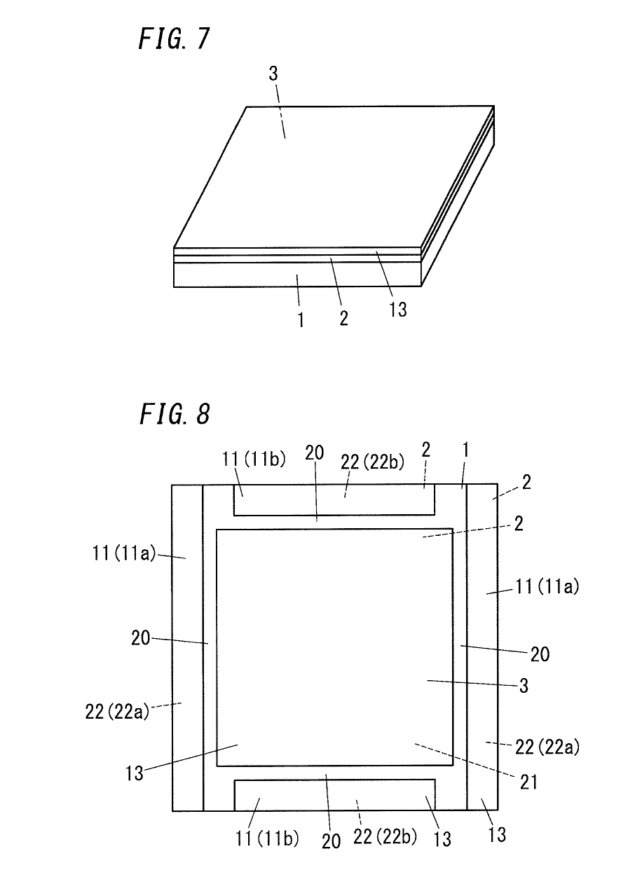

With referring to FIG. 7 to FIG. 12, an example of the production method of the organic EL element 100 is described. FIG. 7 to FIG. 12 shows a process of producing the organic EL elements 100 (100A 100B and 100E) corresponding to the first, second, and fifth embodiments. The organic EL elements 100C and 100D of the third and fourth embodiments shown in FIG. 3 and FIG. 4 can be produced by a similar method to the above. Note that, the following production method is one example, and the organic EL element 100 in accordance with the present invention is not limited to the organic EL element produced by the following production method.

First, as shown in FIG. 7, a substrate material in which the light-outcoupling layer 2 and a transparent electrically conductive layer 13 are stacked on the surface 1a of the light transmissive substrate 1 is prepared. The transparent electrically conductive layer 13 is a layer serving as a base for the first electrode 3, the first extension electrode 11a, and the second extension electrode 11b.

This substrate material can be formed by forming the light-outcoupling layer 2 on the surface 1a of the light transmissive substrate 1 and forming the transparent electrically conductive layer 13 on the surface 2a. Alternatively, the substrate material can be obtained by attaching to the light transmissive substrate 1 the light-outcoupling layer 2 (plastic material) in which the transparent electrically conductive layer 13 is formed on the surface 2a. The light transmissive substrate 1 and the light-outcoupling layer 2 constitute a composite substrate. For example, such attaching can be conducted by attaching a plastic sheet to the surface 1a of the light transmissive substrate 1 of a glass substrate by thermocompression bonding or adhesive. At this time, the composite substrates whose number is equal to the number of elements can be formed.

As a result, as shown in FIG. 7, the light transmissive substrate 1 in which the light-outcoupling layer 2 and the transparent electrically conductive layer 13 are stacked on the surface 1a can be obtained. The central portion of the transparent electrically conductive layer 13 serves as the first electrode 3.

Next, as shown in FIG. 8, the light-outcoupling layer 2 and the first electrode 3 are stacked on the surface 1a of the light transmissive substrate 1 are subjected to a dividing process, so that the light-outcoupling layer 2 is divided into the central portion 21, the first peripheral portion 22a, and the second peripheral portion 22b.

At this time, the first extension electrode 11a is formed on the surface of the first peripheral portion 22a as a result of division of the transparent electrically conductive layer 13, and the second extension electrode 11b is formed on the surface of the second peripheral portion 22b as a result of division of the transparent electrically conductive layer 13. Further, the first electrode 3 defined by the central portion of the transparent electrically conductive layer 13 is formed on the surface of the central portion 21 of the light-outcoupling layer 2.

The dividing (cutting) process of the light-outcoupling layer 2 can be conducted by use of a laser. Thus, the transparent electrically conductive layer 13 and the light-outcoupling layer 2 are partially cut off and thus the recess (groove) 20 is formed. Hence, the light-outcoupling layer 2 can be divided easily.

With using the laser, it is possible to easily cut only the transparent electrically conductive layer 13 and the light-outcoupling layer 2 without cutting the light transmissive substrate 1. Further, with using the laser, when the recess 20 is formed as a result of division of the light-outcoupling layer 2, the light transmissive substrate 1 can be exposed on the bottom of the recess 20. Thus, it becomes easy to successfully separate the light-outcoupling layer 2 into parts with gaps in-between. Further, with using the laser, it can be easy to cut the light-outcoupling layer 2 so as to have an edge that is tapered and has an inclined angle, by adjusting the intensity of a laser beam. Hence, it is possible to easily form the inclined side surface 201 of the recess 20 formed as a result of separation of the light-outcoupling layer 2, by cutting.

Alternatively, the light-outcoupling layer 2 may be cut with a cutting tool such as a cutter. When cutting is performed with the cutter, the inclined surface can be formed by cutting the light-outcoupling layer 2 and the transparent electrically conductive layer 13 in a direction inclined from the surface. Alternatively, the light-outcoupling layer 2 and the transparent electrically conductive layer 13 are cut in a direction perpendicular to the surface and after that the side surface (edge surface of the light-outcoupling layer 2) of the recess 20 may be process to be the inclined surface. When the light-outcoupling layer 2 is cut with the cutter, the light-outcoupling layer 2 may be cut along outer limits of the recess 20 to be formed, and part of the light-outcoupling layer 2 between the cut lines may be peeled off and removed.

In the present production method, the transparent electrically conductive layer 13 for forming the first electrode 3 is formed on the entire surface 2a of the light-outcoupling layer 2 and subsequently the light-outcoupling layer 2 and the first electrode 3 are divided by partially removing the light-outcoupling layer 2 and the first electrode 3. Hence, separating of the light-outcoupling layer 2 and patterning of the electrodes can be performed at the same time, and it is possible to easily form the first electrode 3 and the extension electrode 11. Note that, the light transmissive substrate 1 in which the transparent electrically conductive layer 13 is not formed on the surface 2a of the light-outcoupling layer 2 may be used, and in this case, the light-outcoupling layer 2 is divided and then a patterned conductor defining the first electrode 3 and the extension electrode 11 may be formed.

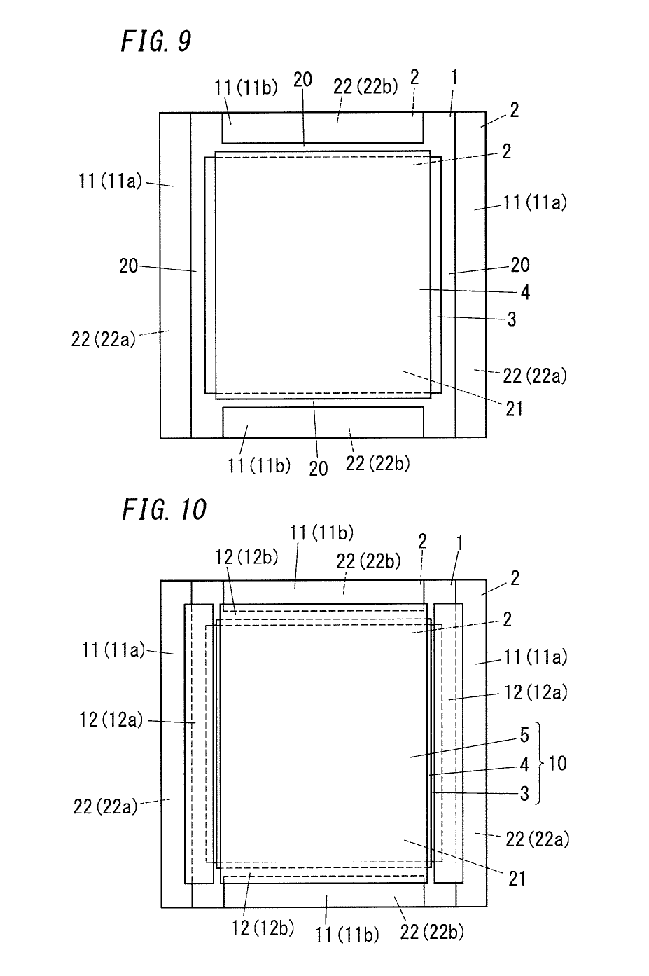

Next, as shown in FIG. 9, the organic layer 4 is formed on the surface of the first electrode 3 formed on the surface of the central portion 21 of the light-outcoupling layer 2.

The organic layer 4 can be formed by stacking layers constituting the organic layer 4 sequentially by deposition or application. The organic layer 4 is formed so that the end of the organic layer 4 close to the second extension electrode 11b slightly extends outside the first electrode 3. By doing so, it is possible to form the second electrode 5 so as not to be in contact with the first electrode 3.

Note that, the end of the first electrode 3 close to the second extension electrode 11b may be positioned slightly more inward than the periphery of the light-outcoupling layer 2 (see FIG. 1(b) and FIG. 2(b)). By doing so, when the organic layer 4 is formed to slightly extend outside the first electrode 3, part of the organic layer 4 is formed on the surface of the light-outcoupling layer 2. On the surface of the light-outcoupling layer 2 and thus it is possible to easily form the organic layer 4 covering the side surface of the first electrode 3. As a result, short-circuiting between the electrodes can be suppressed.

Next, as shown in FIG. 10, the second electrode 5 is formed on the surface of the organic layer 4.

In this process, a layer for the second electrode 5 is formed such that the layer is not in contact with the first electrode 3 but extends to the second extension electrode 11b to cover the surface of the second extension electrode 11b. As a result, the light-emitting stack 10 is formed, and the second electrode 5 and the second extension electrode 11b are electrically interconnected by the second electrode connector 12b which is an extended part from the light-outcoupling layer 2.

Further, by forming a layer of the same material as the second electrode 5 so as to extend between the first electrode 3 and the extension electrode 11 at the time of forming the second electrode 5, the first electrode connector 12a can be formed. To prevent short-circuiting, the first electrode connector 12a is formed so as not to be in contact with the second electrode 5. Additionally, to enable stable light emission, the first electrode connector 12a may be formed so as not to be in contact with the organic layer 4 also.

Such a layer of material of the second electrode 5 can be easily formed by use of a patterned mask. When the electrode connector 12 is formed by the same material as the second electrode 5, a step of forming the electrode connector 12 is unnecessary, and the production can be performed efficiently.

Thereafter, as shown in FIG. 11, a sealing bonding agent is provided, as a dam material, so as to be on the surface (note that, this surface includes part of the surface of the light transmissive substrate 1) of the extension electrode 11 provided to the peripheral portion 22 of the light-outcoupling layer 2 and surround the periphery of the light-emitting stack 10. This darn material is selected so that the dam material can keep its shape even when it has adhesiveness. The sealing bonding agent is material for forming the sealing bond 7.

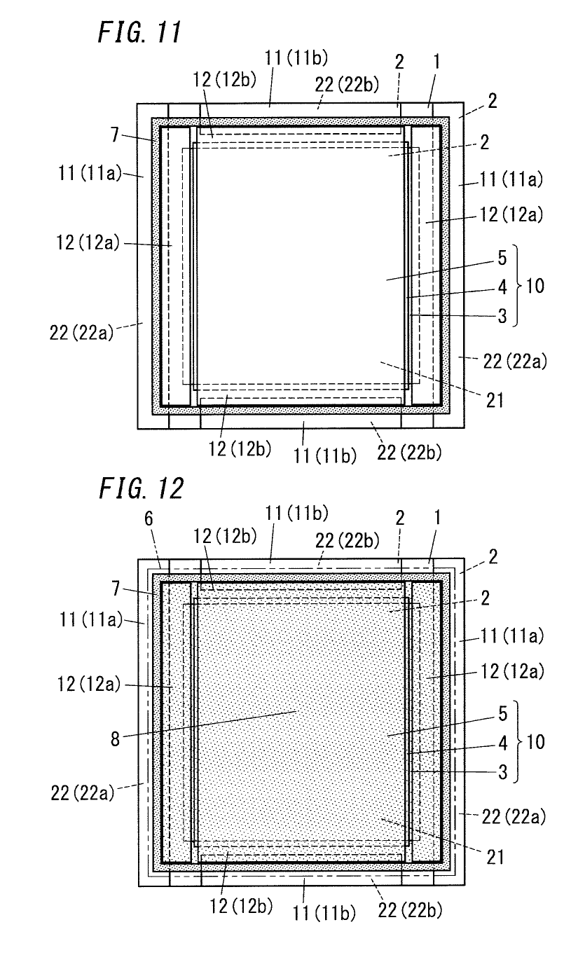

Subsequently, as shown in FIG. 12, a space surrounded by the dam material (sealing bonding agent) is filled with the filler 8. After that, the sealing base 6 is moved close to the surface, on which the light-emitting stack 10 is formed, of the light transmissive substrate 1, and then is bonded to the light transmissive substrate 1 with the sealing bonding agent to enclose the light-emitting stack 10. The sealing bonding agent forms the sealing bond 7.

Through the aforementioned steps, the organic EL element 100A similar to the first embodiment shown in FIG. 1 can be obtained.

Note that, as for the method of producing the organic EL element 100C of the third embodiment shown in FIG. 3, in the step of obtaining the structure shown in FIG. 8 (i.e., in the step of forming the recess 20), the transparent electrically conductive layer 13 is left at the central portion 21 of the light-outcoupling layer 2 but is removed at the peripheral portion 22 of the light-outcoupling layer 2.

Further, in the step of forming the second electrode 5 as shown in FIG. 10, the first extension electrode 11a and the second extension electrode 11b are formed by forming the layer of the material of the second electrode 5 so as to extend outside the sealed region. Thus, the organic EL element 100C of the third embodiment shown in FIG. 3 can be obtained.

Additionally, as for the method of producing the organic EL element 100D of the fourth embodiment shown in FIG. 4, in the step of forming the second electrode 5, the layer of the material of the second electrode 5 may be formed so as to extend outside the sealed region. By doing so, part of the layer of the material of the second electrode 5 exists on the surface of the transparent electrically conductive layer 13 in the outside of the sealed region, and thus the extension electrode 11 with the stack structure is formed. Thus, the organic EL element 100D of the fourth embodiment shown in FIG. 4 can be obtained.

In the production of the organic EL elements 100, the plurality of organic EL elements 100 may be formed so as to have a continuous common light transmissive substrate 1, and then the light transmissive substrate 1 is cut to give the individual organic EL elements 100. Accordingly, the plurality of the organic EL elements 100 may be formed simultaneously. In this case, the plurality of the organic EL elements 100 can be formed simultaneously, and therefore it is possible to improve efficiency in production. When the plurality of organic EL elements 100 are formed simultaneously, the light-outcoupling layer 2 is attached to the entire surface of the common light transmissive substrate 1, and then parts of the light-outcoupling layer 2 individually corresponding to the organic EL elements 100 are divided in an appropriate pattern. Accordingly, each light-outcoupling layer 2 is divided into the central portion 21 and the peripheral portion 22. At this time, the light-outcoupling layer 2 may be divided at regions for separation of the organic EL element 100. By doing so, it is possible to suppress failure of cutting in the process of producing the elements by cutting the light transmissive substrate 1. Similarly to the light transmissive substrate 1, the sealing base 6 may be a continuous common sealing base 6. After sealing, the light transmissive substrate 1 and the sealing base 6 are cut and divided, and as a result the organic EL elements are separate.

### Advantageous Effect

As described above, according to the organic EL elements 100 (100A to 100E) of the first to fifth embodiments, the light-outcoupling layer 2 is provided and thus the light-outcoupling efficiency can be improved. Further, the light-outcoupling layer 2 is divided into the central portion 21 and the peripheral portion 22, and therefore intrusion of moisture into the inside of the element can be inhibited and consequently the element is unlikely to deteriorate. In summary, it is possible to propose the organic EL element 100 with the superior light-outcoupling efficiency and high reliability. Additionally, the organic EL element 100 in accordance with the present invention is useful as a planar light emitter.

1. An organic electroluminescence element comprising:
a substrate;
a light-outcoupling layer situated on a surface of the substrate;
a light-emitting layer situated on a face on an opposite side of the light-outcoupling layer from the substrate;
a sealing base situated facing the face of the light-outcoupling layer; and
a sealing bond formed to enclose the light-emitting layer and bond the sealing base to the face of the light-outcoupling layer,
the light-outcoupling layer including:
a first portion where the light-emitting layer is situated;
a second portion where the sealing bond is situated; and
a groove spatially separating the first portion from the second portion.

2. The organic electroluminescence element according to claim 1, wherein:
the organic electroluminescence element comprises an extension electrode electrically connected to the light-emitting layer; and
the extension electrode is situated between the face of the light-outcoupling layer and the sealing bond so as to extend across the sealing bond.

3. The organic electroluminescence element according to claim 2, wherein
the extension electrode is formed to cover the second portion.

4. The organic electroluminescence element according to claim 2, wherein:
the organic electroluminescence element comprises an electrode connector electrically connecting the light-emitting layer to the extension electrode; and
the electrode connector is formed to extend across the groove along an internal surface of the groove.

5. The organic electroluminescence element according to claim 4, wherein:
the light-emitting layer includes
a first electrode situated on the face of the light-outcoupling layer,
a second electrode situated facing a face on an opposite side of the first electrode from the light-outcoupling layer, and
an organic layer interposed between the first electrode and the second electrode and configured to emit light in response to application of a voltage between the first electrode and the second electrode;
the extension electrode includes a first extension electrode and a second extension electrode;
the electrode connector includes a first electrode connector electrically connecting the first electrode to the first extension electrode and a second electrode connector electrically connecting the second electrode to the second extension electrode; and
the second electrode connector is formed integrally with the second electrode.

6. The organic electroluminescence element according to claim 5, wherein
the first electrode connector is formed of a part separated from an electrically conductive layer to be a base of the second electrode.

7. The organic electroluminescence element according to claim 1, wherein
at least one of both side faces of the groove is an inclined surface that is inclined from the surface of the substrate.

8. The organic electroluminescence element according to claim 1, wherein:
the organic electroluminescence element comprises a protector protecting the light-emitting layer; and
the protector is formed by filling with filler a space enclosed by the substrate, the sealing base, and the sealing bond.

9. The organic electroluminescence element according to claim 8, wherein
the filler contains a hygroscopic agent.

10. The organic electroluminescence element according to claim 2, wherein
a total of a thickness of the extension electrode and a thickness of a portion of the sealing bond positioned on this extension electrode is greater than a thickness of the light-emitting layer.

11. The organic electroluminescence element according to claim 1, wherein
the substrate is made to transmit light emitted from the light-emitting layer.

12. The organic electroluminescence element according to claim 11, wherein:
the light-outcoupling layer includes at least one of a light refraction layer and a light scattering layer;
the light refraction layer is a layer having a refractive index between a refractive index of a portion of the light-emitting layer that is in contact with the light-outcoupling layer and a refractive index of the substrate; and
the light scattering layer is a layer having a structure causing scattering of light emitted from the light-emitting layer.

13. The organic electroluminescence element according to claim 1, wherein
the substrate and the sealing base are made of moisture proof material.
